(19) United States
(12) Patent Application Publication
(10) Pub. No.: US 2026/0171135 A1
(43) Pub. Date: Jun. 18, 2026

(54) MEMORY DEVICE, METHOD OF OPERATING MEMORY DEVICE, AND MEMORY SYSTEM FOR MANAGING ROW HAMMER

(71) Applicant: SAMSUNG ELECTRONICS CO., LTD., Suwon-si (KR)

(72) Inventors: Sunghye CHO, Suwon-si (KR); Eunae LEE, Suwon-si (KR); Kijun LEE, Suwon-si (KR); Myungkyu LEE, Suwon-si (KR); Yejun KO, Suwon-si (KR); Jinwoo SEONG, Suwon-si (KR); Kyomin SOHN, Suwon-si (KR)

(73) Assignee: SAMSUNG ELECTRONICS CO., LTD., Suwon-si (KR)

(21) Appl. No.: 19/251,223

(22) Filed: Jun. 26, 2025

(30) Foreign Application Priority Data
Dec. 17, 2024 (KR) 10-2024-0188712

(51) Int. Cl. G11C 11/406

(52) U.S. Cl. CPC G11C 11/40618; G11C 11/40603; G11C 11/40615

(57) ABSTRACT

A memory device includes memory banks including a memory cell array including a plurality of memory cell rows disposed therein, and each including a row decoder connected to the plurality of memory cell rows; a row hammer management circuit configured to generate a row hammer address; a refresh controller configured to provide one of a normal refresh address for a normal refresh operation, and a row hammer refresh address for a row hammer refresh operation based on the row hammer address to the row decoder as a refresh address; a control logic circuit configured to control the row decoder, the row hammer management circuit, and the refresh controller, wherein each of the plurality of memory cell rows includes count cells configured to store count data corresponding to the number of accesses, wherein the count data includes N bits of lower data and M bits of first upper data.

### CROSS-REFERENCE TO RELATED APPLICATION(S)

This application claims benefit of priority to Korean Patent Application No. 10-2024-0188712 filed on Dec. 17, 2024 in the Korean Intellectual Property Office, the disclosure of which is incorporated herein by reference in its entirety.

### BACKGROUND

Example embodiments of the present disclosure relate to a memory device, a method of operating a memory device, and a memory system for managing row hammer.

To increase capacity and integration density of a memory device, a size of a memory cell has gradually decreased. When repeated access occurs to a specific row of a memory device, a row hammer phenomenon in which data stored in memory cells connected to adjacent rows are affected may occur due to electromagnetic coupling between rows. To reduce data loss due to such row hammer, the memory device may need to swiftly detect an aggressor row intensively accessed during a predetermined period of time and to refresh adjacent rows, a target of modification.

### SUMMARY

An example embodiment of the present disclosure is to provide a memory device which may swiftly detect and defend against row hammer with a small number of queues while preventing estimation of the number of accesses from an external entity.

According to an example embodiment of the present disclosure, a memory device includes a plurality of memory banks including a memory cell array including a plurality of memory cell rows disposed in the memory cell array, wherein each of the memory cell array includes a row decoder connected to the plurality of memory cell rows; a row hammer management circuit configured to generate a row hammer address; a refresh controller configured to provide one of a normal refresh address for a normal refresh operation, and a row hammer refresh address for a row hammer refresh operation based on the row hammer address to the row decoder as a refresh address; a control logic circuit configured to control the row decoder, the row hammer management circuit, and the refresh controller, wherein each of the plurality of memory cell rows includes count cells configured to store count data corresponding to a number of accesses, wherein the count data includes N bits of lower data and M bits of first upper data, where each of M and N is a natural number of being equal to or greater than 1, and wherein an initial value of the lower data is determined arbitrarily, and an initial value of the first upper data is determined as 0.

According to an example embodiment of the present disclosure, a method of operating a memory device includes determining an initial value of upper data among count data representing the number of accesses to each of a plurality of memory cell rows as 0, and determining an initial value of lower data among the count data as a random value; searching a maximum queue having a highest count value corresponding to queue count data among at least one queue stored in a queue register; determining a memory cell row corresponding to an address stored in the maximum queue among a plurality of memory cell rows as an attack row; deleting data stored in the maximum queue; resetting upper data of the attack row to 0; and outputting an address of the attack row as a hammer address in a row hammer management circuit.

According to an example embodiment of the present disclosure, a memory system includes a memory device configured to store data; and a memory controller configured to transmit a command signal, an address signal, a clock signal, and a data signal to the memory device, wherein the memory controller includes a row hammer management circuit configured to generate a row hammer address, wherein the memory device further includes a plurality of memory banks each including a memory cell array in which the plurality of memory cell rows are disposed, and a row decoder connected to the plurality of memory cell rows; a refresh controller configured to provide one of a normal refresh address for a normal refresh operation and a row hammer refresh address for a row hammer refresh operation based on the row hammer address to the row decoder as a refresh address; a control logic circuit configured to control the row decoder, the row hammer management circuit, and the refresh controller, wherein each of the plurality of memory cell rows includes count cells configured to store count data corresponding to a number of accesses, wherein the count data includes N bits of lower data and M bits of upper data, where each of M and N is a natural number of being equal to or greater than 1, and wherein an initial value of the lower data is arbitrarily determined, and an initial value of the upper data is determined as 0.

### BRIEF DESCRIPTION OF DRAWINGS

The above and other aspects, features, and advantages of the present disclosure will be more clearly understood from the following detailed description, taken in combination with the accompanying drawings, in which:

FIGS. 1 and 2 are block diagrams illustrating a memory system according to an example embodiment of the present disclosure;

FIGS. 3 and 4 are block diagrams illustrating a structure of a memory device according to an example embodiment of the present disclosure;

FIG. 5 is a block diagram illustrating a memory bank according to an example embodiment of the present disclosure;

FIG. 6 is a diagram illustrating a count value according to an example embodiment of the present disclosure;

FIG. 7 is a block diagram illustrating a row hammer management circuit according to an example embodiment of the present disclosure;

FIG. 8 is a block diagram illustrating a queue register according to an example embodiment of the present disclosure;

FIG. 9 is a block diagram illustrating a refresh controller according to an example embodiment of the present disclosure;

FIG. 10 is a block diagram illustrating a portion of a memory cell array according to an example embodiment of the present disclosure;

FIG. 11 is a timing diagram illustrating operations of a memory device according to an example embodiment of the present disclosure;

FIG. 12, FIG. 13, FIG. 14, FIG. 15A, FIG. 15B, FIG. 15C, FIG. 15D, and FIG. 15E are flowcharts illustrating operations of a memory system according to an example embodiment of the present disclosure;

FIG. 16A, FIG. 16B and FIG. 16C are diagrams illustrating count values according to an example embodiment of the present disclosure;

FIG. 17 is a block diagram illustrating a row hammer management circuit according to an example embodiment of the present disclosure;

FIG. 18 and FIG. 19 are diagrams illustrating a queue register according to an example embodiment of the present disclosure;

FIG. 20 is a block diagram illustrating a refresh controller according to an example embodiment of the present disclosure;

FIG. 21, FIG. 22, FIG. 23, FIG. 24, FIG. 25, FIG. 26A, FIG. 26B, FIG. 26C, FIG. 27A, FIG. 27B and FIG. 27C are flowcharts illustrating operations of a memory system according to an example embodiment of the present disclosure; and

FIG. 28 is a block diagram illustrating components of a memory controller according to an example embodiment of the present disclosure.

### DETAILED DESCRIPTION

Hereinafter, embodiments of the present disclosure will be described as follows with reference to the accompanying drawings.

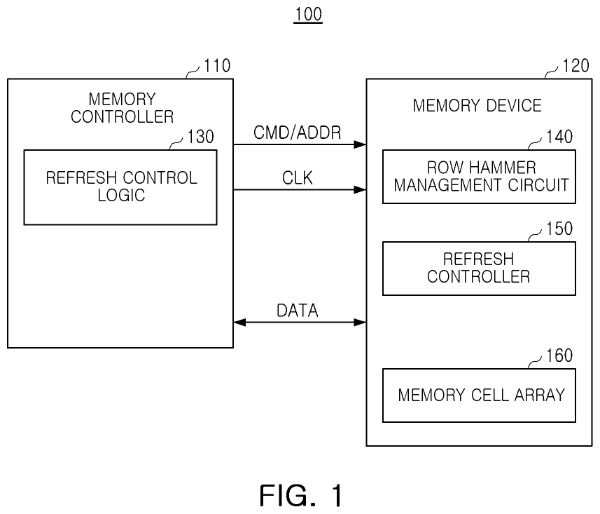

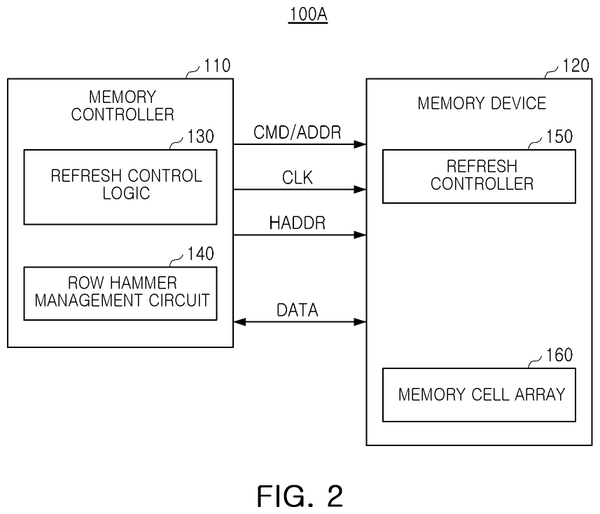

FIGS. 1 and 2 are block diagrams illustrating a memory system according to an example embodiment.

Referring to FIG. 1, a memory system 100 may include a memory controller 110 and a memory device 120. The memory controller 110 and the memory device 120 may be connected to each other through a memory interface and may exchange signals through the memory interface. For example, the memory controller 110 may transmit a command signal CMD, an address signal ADDR, a data signal DATA, and a clock signal CLK to the memory device 120.

The memory device 120 may include a row hammer management circuit 140, a refresh controller 150, and a memory cell array 160. The memory cell array 160 may include a plurality of memory cells for storing data. In an example embodiment, a refresh operation may be performed in units of memory cell rows (hereinafter, “rows”) grouped into a single wordline. The row hammer management circuit 140 may detect an aggressor row intensively accessed among a plurality of rows, and may output an address of the aggressor row, that is, the row hammer address, to the refresh controller 150. The refresh controller 150 may determine a victim row, which is a target of a row hammer refresh operation, based on the row hammer address, and may output an address of a victim row, that is, a row hammer refresh address.

The memory controller 110 may control a memory operation of the memory device 120 by providing a signal to the memory device 120. For example, the memory controller 110 may provide a command signal CMD and an address signal ADDR to the memory device 120, may access the memory cell array 160, and may control a memory operation such as a read or write operation. By performing a read operation, a data signal DATA may be transferred from the memory cell array 160 to the memory controller 110, and by performing a write operation, a data signal DATA may be transferred from the memory controller 110 to the memory cell array 160.

The memory controller 110 may include a refresh control logic 130. The refresh control logic 130 may provide a command signal CMD to the memory device 120 by including a refresh command or a refresh management (RFM) command according to predetermined criteria. The refresh control logic 130 may store the number of accesses for each of the plurality of memory banks. In an example embodiment, the refresh control logic 130 may provide a command signal CMD to the memory device 120 by including a refresh command for a refresh operation for a memory bank when the number of accesses for each of the plurality of memory banks is equal to or greater than a bank access threshold (BAT) value. In another example embodiment, even when the number of accesses for each of the plurality of memory banks is less than the BAT value, when it is determined that it is necessary to manage an aggressor row, the refresh control logic 130 may provide a command signal CMD to the memory device 120 by including a RFM command.

The command signal CMD may include an activate command, a read/write command, a refresh command, and an RFM command. The activate command may be a command to switch an access row of the memory cell array 160 to an active state to write data to the memory cell array 160 or to read data from the memory cell array 160. A memory cell of the access row may be activated in response to the activate command. The read/write command may be a command to perform a read or write operation on a memory cell switched to an active state.

The refresh command and the RFM command may be commands to perform a refresh operation on the access row. In an example embodiment, the refresh controller 150 may output a normal refresh address or a row hammer refresh address in response to the refresh command, or may output a row hammer refresh address in response to the RFM command. The normal refresh address may be an address for a normal refresh operation, for example, to sequentially refresh rows of the memory cell array 160. The row hammer refresh address may be an address of a victim row which is a target of a row hammer refresh operation based on the row hammer address.

Referring to FIG. 2, the memory system 100A may include a memory controller 110 and a memory device 120. The memory controller 110 may include a refresh control logic 130 and a row hammer management circuit 140. The memory device 120 may include a refresh controller 150 and a memory cell array 160. The refresh control logic 130, the row hammer management circuit 140, the refresh controller 150, and the memory cell array 160 may be similar to those described above with reference to FIG. 1. However, differently from the memory system 100 according to FIG. 1, the memory system 100A according to FIG. 2 may include the row hammer management circuit 140 in the memory controller 110. Also, the memory system 100A according to FIG. 2 may transfer the row hammer address HADDR provided by the row hammer management circuit 140 from the memory controller 110 to the memory device 120. That is, according to an example embodiment, the row hammer management circuit 140 may be included in the memory controller 110 or may be included in the memory device 120.

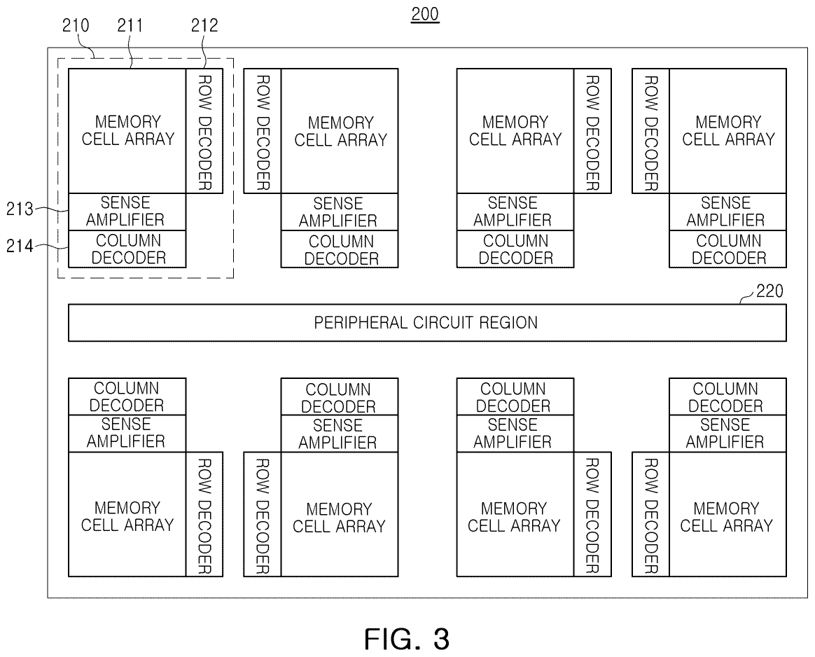

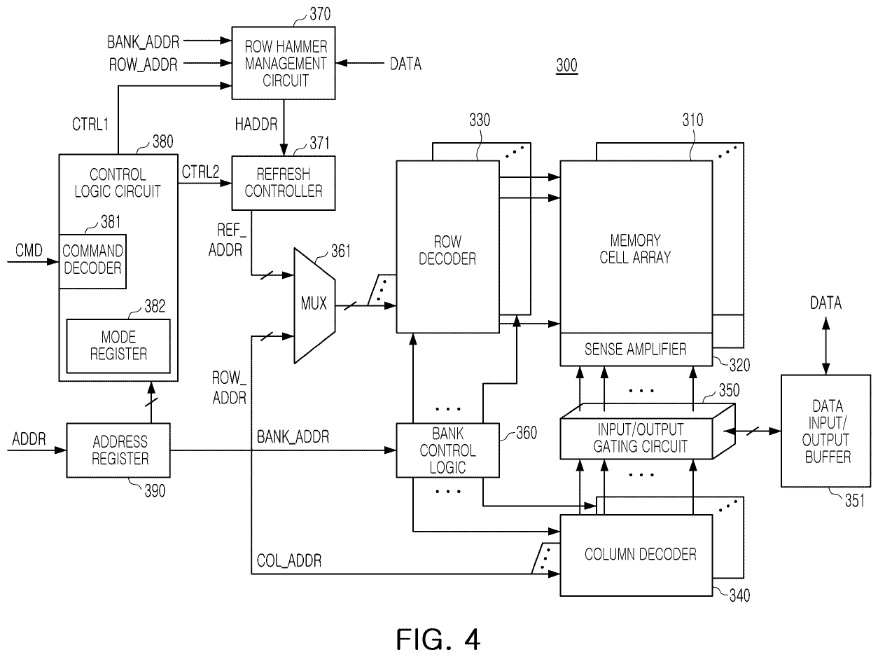

FIGS. 3 and 4 are block diagrams illustrating a structure of a memory device according to an example embodiment.

Referring to FIG. 3, a memory device 200 according to an example embodiment, may include a cell region in which a plurality of memory banks 210 are disposed, and a peripheral circuit region 220. Each of the plurality of memory banks 210 may include a memory cell array 211, a row decoder 212, a sense amplifier circuit 213, and a column decoder 214. The plurality of memory cells included in the memory cell array 211 may be connected to the row decoder 212 through a plurality of wordlines, and may be connected to the sense amplifier circuit 213 through a plurality of bitlines. In the example embodiment illustrated in FIG. 3, eight memory banks 210 are included in the memory device 200, but the number of memory banks 210 may be varied in example embodiments.

The peripheral circuit region 220 may include a logic circuit configured to control a plurality of memory banks 210, an input/output circuit configured to exchange signals with other external devices, such as a memory controller. In an example embodiment, the peripheral circuit region 220 may control a program operation, read operation, refresh operations, or the like, of each of the plurality of memory banks 210 based on a command signal and an address signal received from the memory controller.

Referring to FIG. 4, the memory device 300 may include a plurality of memory cell arrays 310, a plurality of row decoders 330, a plurality of sense amplifier circuits 320, a plurality of column decoders 340, an address register 390, or the like. The memory cell array 310, the row decoder 330, the sense amplifier 320, and the column decoder 340 may be included in a plurality of memory banks.

The control logic circuit 380 may include a command decoder 381 and a mode register 382, or the like. The command decoder 381 may receive a command signal CMD from an external memory controller, or the like, and may control a plurality of memory banks based on the command signal CMD. In an example embodiment, when a refresh command or a RFM command is included in the command signal CMD, the command decoder 381 may decode the command signal CMD and may provide a first control signal CTRL1 to the row hammer management circuit 370 and a second control signal CTRL2 to the refresh controller 371. The mode register 382 may include a plurality of registers configured to store information for determining the operating environment of the memory device 300.

The control logic circuit 380 may schedule a row hammer refresh timing for performing a row hammer refresh operation and a normal refresh timing for performing a normal refresh operation. In an example embodiment, the control logic circuit 380 may provide a second control signal CTRL2 to the refresh controller 371 to have one row hammer refresh timing after three normal refresh timings when receiving a command signal CMD including a refresh command. In another example embodiment, the control logic circuit 380 may provide a second control signal CTRL2 to the refresh controller 371 to perform a row hammer refresh operation when receiving a command signal CMD including an RFM command. However, the ratio and the provision order of the normal refresh timing and the row hammer refresh timing may be varied in example embodiments.

The memory cell array 310 may include a plurality of memory cells, and each of the plurality of memory cells may be connected to the row decoder 330 through a wordline and may be connected to the sense amplifier 320 through a bitline.

The address register 390 may receive an address signal ADDR from the memory controller, or the like. The address register 390 may decode the address signal ADDR and may generate a bank address BANK_ADDR indicating a target memory bank among a plurality of memory banks, a row address ROW_ADDR indicating a target wordline among a plurality of wordlines included in the target memory bank, and a column address COL_ADDR indicating a target bitline among a plurality of bitlines included in the target memory bank. The bank address BANK_ADDR may be provided to the bank control logic 360, the row address ROW_ADDR may be provided to the multiplexer 361, and the column address COL_ADDR may be provided to the column decoder 340.

The column decoder 340 may select a target bitline among the plurality of bitlines based on the column address COL_ADDR. The column decoder 340 may activate a sense amplifier corresponding to the column address COL_ADDR among the plurality of sense amplifiers 320 through the input/output gating circuit 350. The input/output gating circuit 350 may gate input/output data and may include a data latch for storing data read from the memory cell array 310 and a write driver for writing data to the memory cell array 310. The sense amplifier 320 may read data of memory cells connected to a target wordline and a target bitline in the memory cell array 310 and may store data in a data latch of the input/output gating circuit 350.

In an example embodiment, data obtained from the memory cell array 310 by the sense amplifier 320 by a read operation may be output as a data signal DATA through the data input/output buffer 351 and may be provided to the memory controller. In another example embodiment, data to be stored in the memory cell array may be received as a data signal DATA by the memory controller and may be provided to the data input/output buffer 351, and the data provided to the data input/output buffer 351 may be provided to the input/output gating circuit 350.

The row hammer management circuit 370 may select and manage a continuously accessed aggressor row by referencing at least one candidate aggressor row address stored in a separate queue. The row hammer management circuit 370 may provide a row hammer address HADDR indicating the aggressor row to the refresh controller 371 in response to a first control signal CTRL1.

The refresh controller 371 may provide, to a multiplexer 361, a refresh row address REF_ADDR indicating a victim row on which a refresh operation is to be executed based on the row hammer address HADDR transferred from the row hammer management circuit 370 in response to a second control signal CTRL2 received from the control logic circuit 380.

The multiplexer 361 may receive the refresh row address REF_ADDR from the refresh controller 371 and the row address ROW_ADDR from the address register 390. When the multiplexer 361 selects the refresh row address REF_ADDR, the row decoder 330 may activate a wordline on which the refresh operation is to be executed.

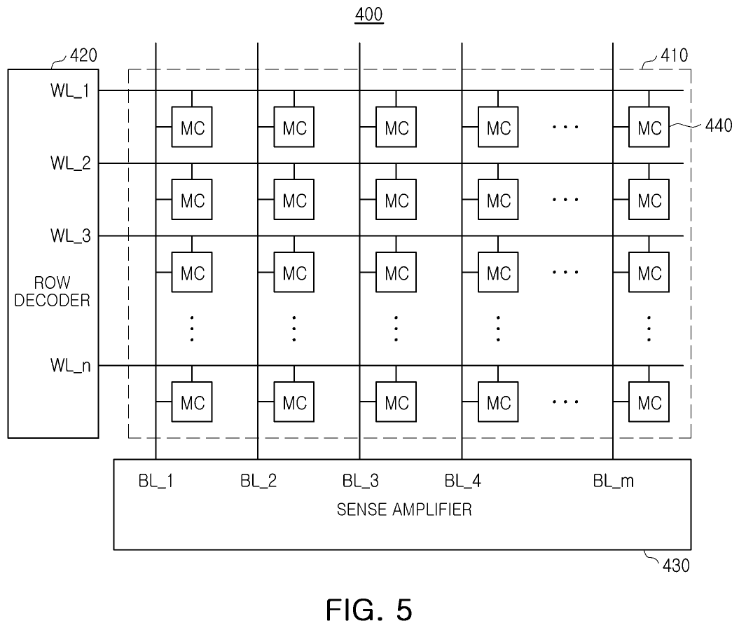

FIG. 5 is a block diagram illustrating a memory bank according to an example embodiment.

Referring to FIG. 5, a memory bank 400 may include a memory cell array 410, a row decoder 420, and a sense amplifier 430. The memory cell array 410 may be connected to the row decoder 420 through a plurality of wordlines WL_1-WL_n, and may be connected to the sense amplifier 430 through a plurality of bitlines BL_1-BL_m. The plurality of wordlines WL_1-WL_n and the plurality of bitlines BL_1-BL_m may be connected to a plurality of memory cells MC 440. Each of the plurality of memory cells MC 440 may include a switch and a cell capacitor, or the like.

When the memory controller accesses a specific row by activating at least one of the plurality of wordlines WL_1-WL_n, the row decoder 420 may activate a wordline corresponding to the access row among the plurality of wordlines WL_1-WL__n. In this case, the memory controller may perform read, write, or refresh operations on the access row.

When the row decoder 420 repeatedly selects and activates a specific wordline among the plurality of wordlines WL_1-WL__n, the rows corresponding to adjacent other wordlines, that is, memory cells MC included in the victim rows, may be interfered with due to electromagnetic coupling between wordlines. In this case, unintended data modification, such as flipping a bit value of data of the memory cells MC, may be induced. Such row hammer phenomenon may become more severe as integration density of the memory device 400 increases.

To prevent data fluctuations in victim rows due to the row hammer phenomenon, a row hammer refresh operation may be performed at a refresh timing. Differently from a normal refresh operation sequentially activating a plurality of wordlines WL_1-WL_n and overwriting data in the memory cells MC, the row hammer refresh operation may specify victim rows of an aggressor row corresponding to a wordline intensively accessed and may overwrite data in the memory cells MC included in the victim rows.

To select an aggressor row, each of the memory cell rows may have count cells which may store count data. The count data may be a binarized count value representing the number of accesses of each of memory cell rows. In an example embodiment, when a count value of an access row is equal to or greater than a predetermined reference value, an address of the access row may be stored in a queue and may become a target of management as a candidate aggressor row. Here, the management of the candidate aggressor row may indicate that the candidate aggressor row is selected as the aggressor row, and the victim rows for the aggressor row are refreshed at a refresh timing.

However, when the initial value of the count data is 0, it may be predicted when the external count value of a specific row becomes greater than a predetermined reference value, when the specific row is selected as the aggressor row, and when a refresh operation is performed, which may be exploited to intentionally manipulate the specific row to not be managed. When the initial value of the count data is determined as a random value, a large number of additional queues may be required to determine whether the number of accesses of the access row is equal to or greater than the predetermined reference value, such that the storage space of the memory device may be wasted. In an example embodiment, a method for maintaining high defense against a row hammer attack even with a small number of queues may be suggested.

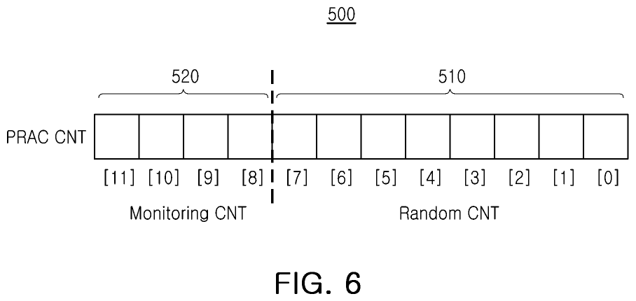

FIG. 6 is a diagram illustrating a count value according to an example embodiment.

Referring to FIG. 6, a portion of memory cells included in a plurality of memory cell rows, which are count cells, may store count data 500 obtained by binarizing a per row activation counting (PRAC) count value representing the number of accesses of each of the plurality of memory cell rows. Whenever a memory cell row is accessed, the PRAC count value PRAC CNT of the memory cell row may be increased by 1.

In an example embodiment, the count cells store count data 500 corresponding to the PRAC count value, and each of the count cells may store 1 bit of data. A portion of the count cells may store N bits of lower data 510, and the other portion of the count cells may store M bits of upper data 520. The lower data 510 may correspond to a random count value random CNT, and the upper data 520 may correspond to a monitoring count value monitoring CNT. For example, each of M and N may be a natural number of being equal to or greater than 1.

According to an example embodiment, a ratio of the upper data 520 to the lower data 510 may be arbitrarily varied. For example, the size of the lower data 510 may be 8 bits, and the size of the upper data 520 may be 4 bits. In another example embodiment, the ratio of the size of the upper data 520 to the size of the count data 500 may be equal to or greater than 30%. However, the ratio of the upper data 520 to the lower data 510 according to an example embodiment is not limited thereto.

Also, the count cells configured to store the upper data 520 and the count cells configured to store the lower data 510 in the count cells may be stored in arbitrary positions in the count cells. For example, among the count cells, odd-numbered count cells may store the upper data 520, and even-numbered count cells may store the lower data 510. However, the positions of count cells configured to store the upper data 520 and the lower data 510 according to an example embodiment are not limited thereto.

In an example embodiment, when booting the memory device, the initial value of the lower data 510 among pieces of count data 500 of the plurality of memory cell rows may be determined as a random value, and the initial value of the upper data 520 among pieces of count data 500 may be determined as 0. Thereafter, whenever a memory cell row is accessed, the PRAC count value PRAC CNT of the memory cell row may be increased by 1. When the PRAC count value PRAC CNT becomes a predetermined reference value or more, the access row may become a target of management as a candidate aggressor row. For example, the count data 500 may be 12-bit data including 4-bit upper data 520 and 8-bit lower data 510. In this case, when the PRAC count value PRAC CNT is 256 or more, that is, when the monitoring count value monitoring CNT is greater than 0, the access row may be a target of management as a candidate aggressor row.

When the candidate aggressor row is selected as the aggressor row at the refresh timing, the victim rows based on the aggressor row may perform a refresh operation, and the PRAC count value PRAC CNT of the aggressor row may be initialized. When the PRAC count value PRAC CNT of the aggressor row is initialized, the random count value random CNT of the aggressor row is maintained, and only the monitoring count value monitoring CNT may be initialized to 0. That is, the lower data 510 may be maintained regardless of the initialization, and each bit of the upper data 520 may be reset to 0.

In an example embodiment, when booting the memory device, the monitoring count value monitoring CNT of the PRAC count value PRAC CNT may be determined as 0 and the random count value random CNT may be determined as a random value. Accordingly, it may be controlled to prevent prediction of a count value externally, that is, to prevent prediction of when an access row is queued as a candidate aggressor row and when managed as an aggressor row. Also, it may be controlled to initialize only the monitoring count value monitoring CNT to 0 while maintaining the random count value random CNT of the aggressor row at the row hammer refresh timing. Accordingly, it may be difficult to predict the count value of memory cell rows externally while the memory device operates, and to defend against a row hammer attack with a small number of queues.

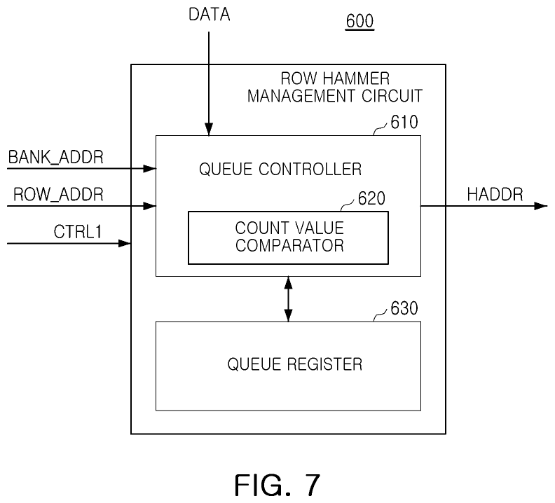

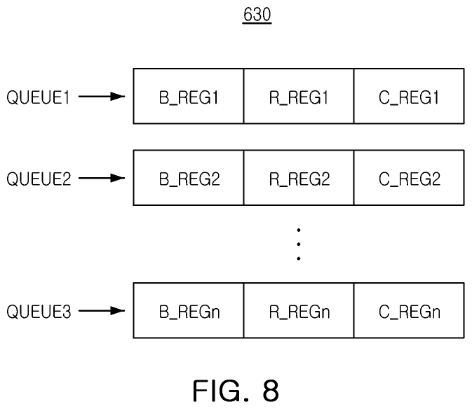

FIG. 7 is a block diagram illustrating a row hammer management circuit according to an example embodiment. FIG. 8 is a block diagram illustrating a queue register according to an example embodiment.

Referring to FIG. 7, a row hammer management circuit 600 may include a queue controller 610 and a queue register 630. The queue register 630 may store information about candidate aggressor rows intensively accessed among access rows. The queue register 630 may include at least one queue to store an address of the candidate aggressor rows and the count data of each of the candidate aggressor rows as count data.

Referring to FIG. 8, each queue may include a bank register B_REG1-B_REGn configured to store the address of each memory bank, a row register R_REG1-R_REGn configured to store each row address, and a count register C_REG1-C_REGn configured to store each count data as count data. A queue may be a storage space implemented with a flip-flop, a latch, a buffer circuit, a static random access memory (SRAM), or the like, and may operate in a first-in-first-out (FIFO) manner. In an example embodiment, the count registers C_REG1-C_REGn of the queue may store upper data among the count data as the count data. However, the count data stored by the queue according to an example embodiment is not limited thereto.

In an example embodiment, a memory device maintaining high defense against a row hammer attack while performing a row hammer refresh operation with one queue may be provided. However, the number of queues according to an example embodiment is not limited thereto.

Referring to FIGS. 7 and 8, a queue controller 610 may include a count value comparator 620. The count value comparator 620 may compare the count data stored in the count registers C_REG1-C_REGn of the queue register 630 with the count data of the access row.

The queue controller 610 may control the queue register 630 based on the address signals BANK_ADDR and ROW_ADDR and the first control signal CTRL1 received from the memory controller. The address signals BANK_ADDR and ROW_ADDR may include a bank address BANK_ADDR and a row address ROW_ADDR. The queue controller 610 may change data stored in the queue based on the comparison result of the count value comparator 620. The aggressor row may be determined among the candidate aggressor rows based on the count data stored in the count registers C_REG1-C_REGn of the queue register 630 according to the first control signal CTRL1, and a hammer address HADDR indicating an address of the aggressor row may be provided. In an example embodiment, when data is stored in the queue, a control logic circuit receiving a refresh command from the memory controller may transmit the first control signal CTRL1 to output a row hammer address for a row hammer refresh operation.

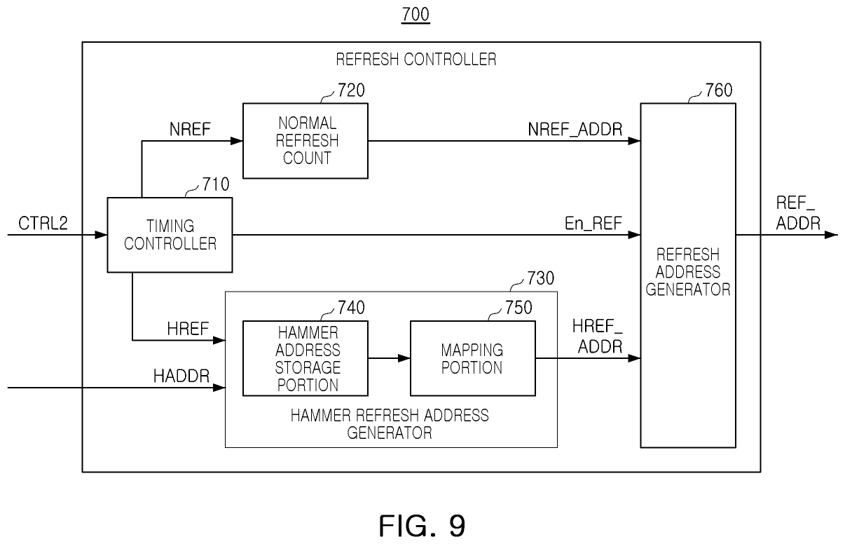

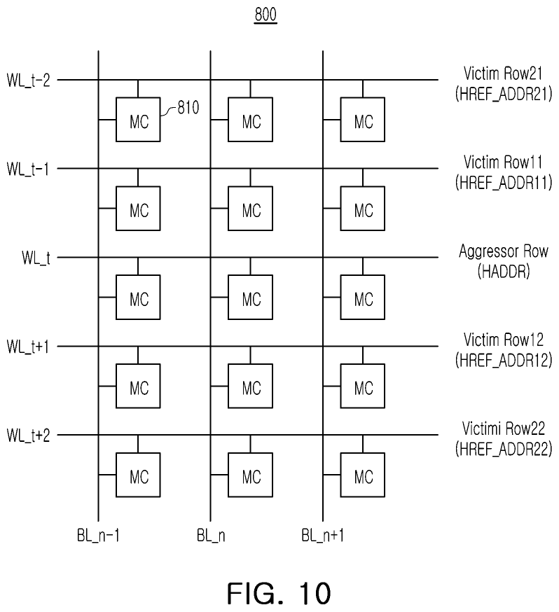

FIG. 9 is a block diagram illustrating a refresh controller according to an example embodiment. FIG. 10 is a block diagram illustrating a portion of a memory cell array according to an example embodiment.

Referring to FIG. 9, a refresh controller 700 may include a timing controller 710, a normal refresh count 720, a hammer refresh address generator 730, and a refresh address generator 760.

The timing controller 710 may receive a second control signal CTRL2 from the memory controller and may output a normal refresh signal NREF to the normal refresh counter 720 or a row hammer refresh signal HREF signal to the hammer refresh address generator 730. In an example embodiment, when no data is stored in a queue of the queue register, the timing controller 710 may output a normal refresh signal NREF to the normal refresh counter 720 to execute a normal hammer refresh operation at the refresh timing. In another example embodiment, when data is stored in the queue, the timing controller 710 may output a row hammer refresh signal HREF to the hammer refresh address generator 730 to execute a row hammer refresh operation at the refresh timing.

In an example embodiment, the normal refresh counter 720 may provide a normal refresh address NREF_ADDR representing an address changing sequentially in synchronization with the normal refresh signal NREF. For example, the normal refresh counter 720 may increase a value of the normal refresh address NREF_ADDR by 1 whenever the normal refresh signal NREF is activated. By increasing the value of the normal refresh address NREF_ADDR by 1 as above, wordlines for the normal refresh operation may be selected in sequence one by one.

The hammer refresh address generator 730 may output the row hammer refresh address HREF_ADDR based on the row hammer address HADDR provided from the row hammer management circuit. The hammer refresh address generator 730 may include a hammer address storage portion 740, and a mapping portion 750.

The hammer address storage portion 740 may store the row hammer address HADDR provided from the row hammer management circuit. The mapping portion 750 may output a row hammer refresh address HREF_ADDR based on a hammer address HADDR provided from the hammer address storage portion 740. The row hammer refresh address HREF_ADDR may be an address of a row physically adjacent to a row corresponding to the row hammer address HADDR. In example embodiments, the hammer address storage portion 740 may not be provided, and in this case, the mapping portion 750 may directly receive the row hammer address HADDR from the row hammer management circuit.

The refresh address generator 760 may receive a normal refresh address NREF_ADDR from the normal refresh count 720 and a hammer refresh address HREF_ADDR from the hammer refresh address generator. The refresh address generator 760 may select one of the normal refresh address NREF_ADDR and the hammer refresh address HREF_ADDR based on an enable signal En_REF received from the timing controller 610 and may output the refresh row address REF_ADDR.

Referring to FIG. 10, a plurality of memory cells MC 810 connected to five wordlines WL_t-2, WL_t-1, WL_t, WL_t+1, and WL_t+2, a plurality of bitlines BL_n-1, BL_n, and BL_n+1 and a plurality of memory cells MC connected to the wordlines WL_t-2, WL_t-1, WL_t, WL_t+1, and WL_t+2 are illustrated. In an example embodiment, the middle wordline WL_t may correspond to an aggressor row intensively accessed. Here, the intensively access may indicate that the number of active times of the wordline is relatively great or that the activation frequency is relatively high. When the aggressor row is accessed, activated and precharged, that is, when the voltage of wordline WL_t of the aggressor row intensively increases and decreases, the voltages of adjacent wordlines WL_t-2, WL_t-1, WL_t+1, and WL_t+2 increase and decrease together due to electromagnetic coupling occurring between adjacent wordlines WL_t-2, WL_t-1, WL_t+1, WL_t+2, which may affect the cell charge of the memory cells MC connected to adjacent wordlines WL_t-2, WL_t-1, WL_t+1, and WL_t+2. As the number of times wordline WL_t of the aggressor row is accessed increases, it may be highly likely that the cell charge of the memory cells MC connected to adjacent wordlines WL_t-2, WL_t-1, WL_t+1, and WL_t+2 may be lost, and the stored data may be damaged.

Referring to FIGS. 9 and 10, the mapping portion 750 may provide addresses HREF_ADDR11, HREF_ADDR12, HREF_ADDR21, and HREF_ADDR22 of the wordlines WL_t-2, WL_t-1, WL_t+1, the WL_t+2 physically adjacent to the row WL_t corresponding to the row hammer address HADDR as hammer refresh address HREF_ADDR, and may perform a row hammer refresh operation for adjacent wordlines WL_t-2, WL_t-1, WL_t+1, and WL_t+2 based on the hammer refresh address HREF_ADDR. Accordingly, data corruption of the memory cells MC due to intensive access may be prevented.

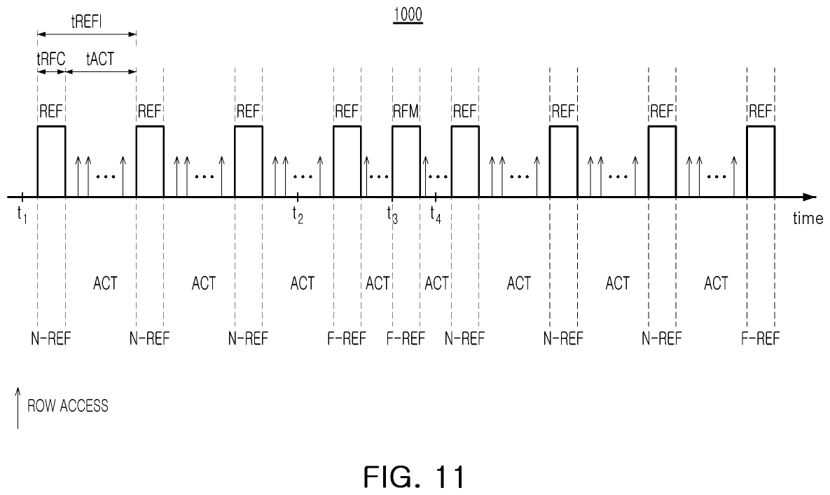

FIG. 11 is a timing diagram illustrating operations of a memory device according to an example embodiment.

Referring to FIG. 11, a memory device 1000 may perform a refresh operation N-REF and F-REF at refresh timing tREF receiving a refresh command REF or RFM command, and memory cell rows may be accessed at other timings, which are active timings tACT. The refresh timing tREF may occur periodically according to a predetermined period of time, or non-periodically whenever predetermined criteria are satisfied.

In an example embodiment, when the number of accesses to each of the plurality of memory banks is a BAT value or more, a refresh control logic of the memory controller may be provided to the memory device by including a refresh command for the corresponding memory bank in the command signal. For example, the BAT value may be 256.

In another example embodiment, even when the number of accesses is less than the BAT value, the refresh control logic may provide, to the memory device 120, an RFM command by including the command in the command signal at a time point at which it may be necessary to manage the aggressor row. In another example embodiment, the refresh period tREFI may be determined as a constant value, for example, 7.8 μs, such that the refresh timing tREF arrives periodically. However, the refresh timing tREF and the active timing tACT according to an example embodiment are not limited thereto.

The refresh operation N-REF and F-REF may be performed as a normal refresh operation N-REF or a row hammer refresh operation F-REF depending on whether a candidate row hammer address is stored in the queue. For example, four operations may be performed at one refresh timing tREF. However, the number of operations which may be performed at the refresh timing tREF according to an example embodiment is not limited thereto.

In an example embodiment, data may not be stored in the queue from a first time point t1 to a second time point t2. In this case, a normal refresh operation N-REF may be performed during a refresh timing tREF. Thereafter, a candidate aggressor row address may be stored in the queue at the second time point t2. At the refresh timing tREF arriving after the second time point t2, a row hammer refresh operation F-REF may be performed instead of the normal refresh operation N-REF. At the third time point t3, the refresh control logic may determine that it may be necessary to manage the candidate aggressor row and an RFM command may be transmitted to the memory device.

In this case, the memory device may stop the row access operation and may perform the row hammer refresh operation F-REF. Thereafter, as the row hammer refresh operation F-REF is completed, data may not be stored in the queue at a fourth time point t4. In this case, a normal refresh operation N-REF may be performed again during the next refresh timing tREF.

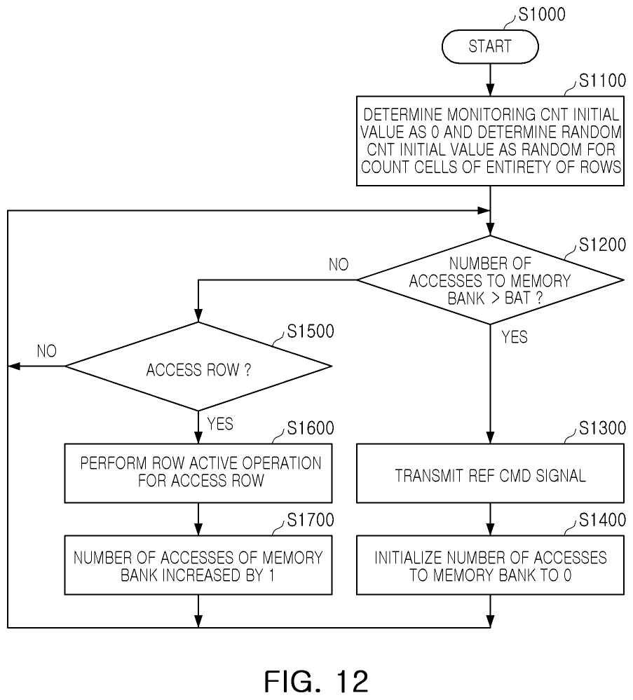

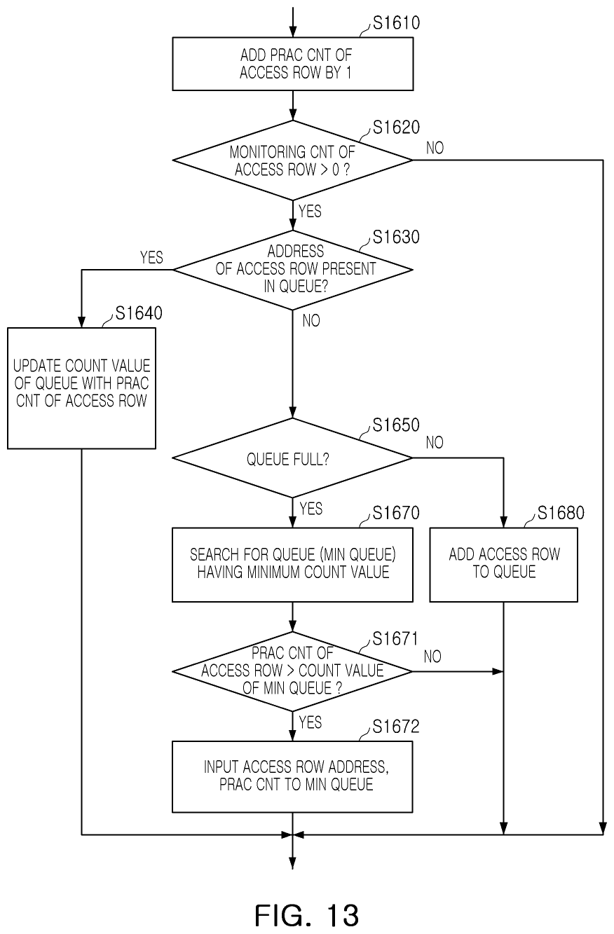

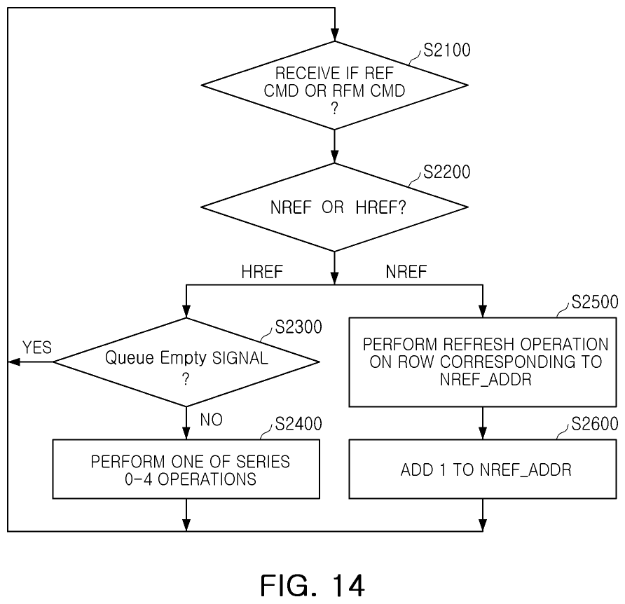

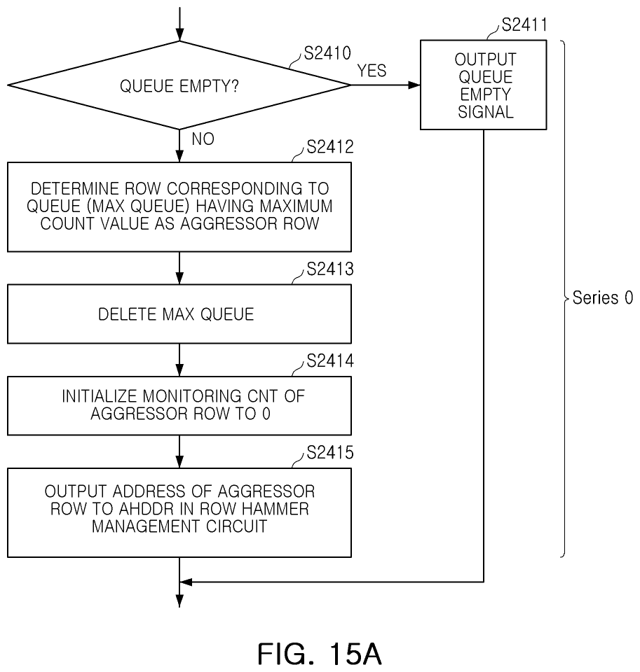

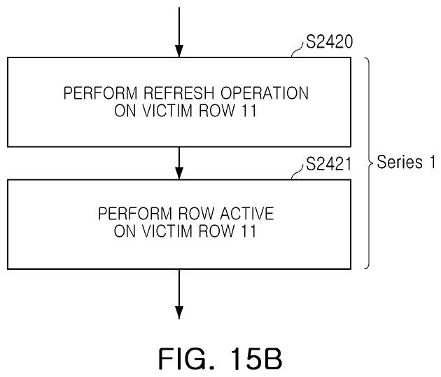

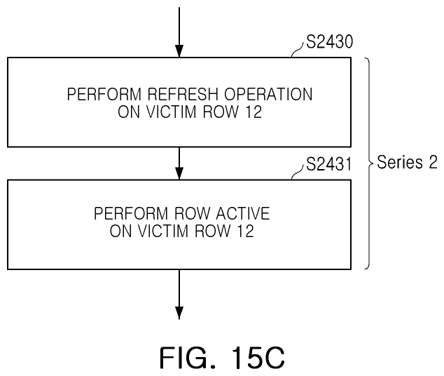

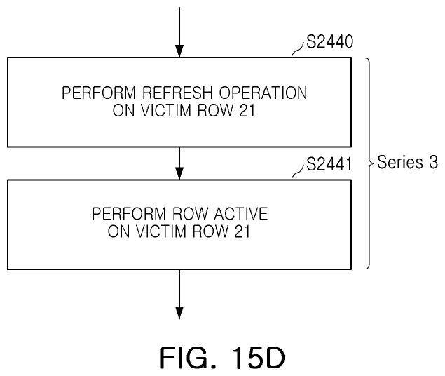

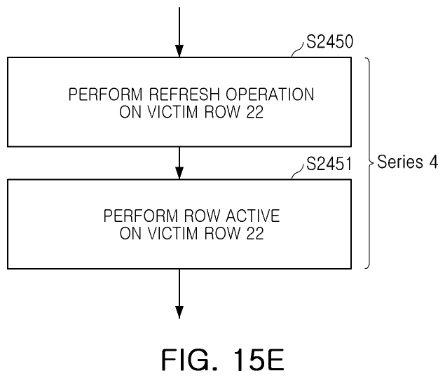

FIGS. 12 to 15E are flowcharts illustrating operations of a memory system according to an example embodiment.

Referring to FIG. 12, when a memory device starts booting (S1000), before a memory controller and the memory device exchange data, the refresh control logic may arbitrarily determine an initial value of the lower data for a PRAC count value of count cells of the entirety of memory cell rows of the memory device and may collectively determine an initial value of upper data as 0 (S1100). In other words, the monitoring count value may be determined as 0 and the random count value may be determined as a random value for each memory cell row. Thereafter, during an active timing, the refresh control logic may compare the number of accesses of each of the plurality of memory banks with the BAT value (S1200).

When the number of accesses of at least one of the plurality of memory banks is the BAT value or more, the refresh control logic may include a refresh command in the command signal and may transmit the command to the memory device (S1300). Thereafter, the refresh control logic may initialize the number of accesses for the corresponding memory bank to 0 (S1400).

When the entirety of the plurality of memory banks have the number of accesses less than the BAT value, the memory controller may access the memory cell row, and the refresh control logic may sense the access (S1500). When the access to the memory cell row is sensed, a row active operation may be performed for the access row (S1600). Thereafter, the number of accesses of the memory bank including the access row may be increased by 1 (S1700).

FIG. 13 may be a flowchart illustrating a row active operation described with reference to FIG. 12. As described above, when the access to the memory cell row is sensed, a row active operation may be performed for the access row. First, the PRAC count value of the access row may be increased by 1 (S1610). Thereafter, it may be determined whether the monitoring count value corresponding to the upper data of the PRAC count value is greater than 0, that is, whether data is input to the upper data (S1620).

When the monitoring count value is 0, it may not be necessary to manage the access row. When the monitoring count value is greater than 0, it may be determined that it may be necessary to manage the access row. In this case, it may be determined whether the address of the access row is present in the queue (S1630). When the address of the access row is present in the queue, the count value corresponding to the count data of the queue configured to store the address of the access row may be updated to the PRAC count value corresponding to the count data of the access row (S1640). On the contrary, when the address of the access row is not present in the queue, an empty space to store the address of the access row in the queue may be required. In this case, it may be determined whether the queue is full (S1650).

When there is an empty space in the queue to store the address of the access row, the address and count data of the access row may be newly stored in the empty queue (S1680). When the queue is full, the pieces of count data stored in the queue may be compared with each other to search for a minimum queue having a smallest count value (S1670). Thereafter, the count value of the minimum queue may be compared with the PRAC count value of the access row (S1671). When the PRAC count value of the access row is greater than the count value of the minimum queue, the candidate row hammer address stored in the minimum queue may be changed to the address of the access row, and the count data stored in the minimum queue may be changed to the count data corresponding to the PRAC count value of the access row (S1672).

FIG. 14 may be a flowchart illustrating a refresh operation. Referring to FIG. 9, when the control logic circuit receives a refresh command or RFM command from the memory controller (S2100), it may provide a second control signal CTRL2 to the refresh controller for the refresh operation. The timing controller 710 receiving the second control signal CTRL2 may transmit a normal refresh signal NREF to the normal refresh counter 720, or may transmit a row hammer refresh signal HREF to the hammer refresh address generator 730 (S2200).

When the timing controller 710 outputs the normal refresh signal NREF, the memory device may perform a normal refresh operation (S2500). The normal refresh counter 620 may provide a normal refresh address NREF_ADDR indicating an address changing sequentially in synchronization with the normal refresh signal NREF. For example, the normal refresh counter 720 may increase the value of the normal refresh address NREF_ADDR by 1 whenever the normal refresh signal NREF is activated (S2600). By increasing the value of the normal refresh address NREF_ADDR by 1, the wordlines for the normal refresh operation may be selected in sequence one by one.

When the timing controller 710 outputs the row hammer refresh signal HREF to the hammer refresh address generator 730, the row hammer refresh operation may be performed. Before performing the refresh operation, the control logic may determine whether a signal indicating that the queue is empty is provided (S2300). When the signal indicating that the queue is not provided, a plurality of series operations Series0-Series4 may be performed in sequence (S2400). In an example embodiment, two series operations may be performed during one refresh timing. In another example embodiment, four series operations may be performed during one refresh timing. However, the number of operations which may be performed during a single refresh timing may be varied in example embodiments.

FIGS. 15A to 15E may be flowcharts illustrating a plurality of series operations Series0-Series4 described with reference to FIG. 14. The plurality of series operations Series0-Series4 may be performed sequentially over a plurality of row hammer refresh timings.

FIG. 15A illustrates a 0th series operation Series0. Referring to FIG. 15A, first, by determining a control logic circuit may determine whether a queue is empty, it may be determined whether to perform a row hammer refresh operation (S2410). When the queue is empty, the control logic circuit may output a signal indicating that the queue is empty (S2411), and thereafter, the row hammer refresh operation may not be performed during the refresh timing during which the corresponding series operation is performed. When the queue is not empty, a maximum queue (Max Queue) having the largest value among the count data stored in the queue may be found, and the candidate row address stored in the maximum queue may be selected as the aggressor row (S2412). Thereafter, the maximum queue may be deleted (S2413), and the upper data among the count data of the aggressor row may be reset to 0 (S2414). That is, the monitoring count value of the aggressor row may be reset to 0. Thereafter, the row hammer management circuit may output the address of the aggressor row to the refresh controller as the hammer address HADDR (S2415).

The refresh controller may generate a plurality of row hammer refresh addresses HREF_ADDR in sequence based on the hammer address HADDR. The row hammer refresh address HREF_ADDR may be an address of a row physically adjacent to the row corresponding to the row hammer address HADDR. In an example embodiment, referring to FIG. 10, the refresh controller may output hammer refresh addresses HREF_ADDR representing an eleventh hammer refresh address HREF_ADDR11 of an eleventh victim row, a twelfth hammer refresh address HREF_ADDR12 of a twelfth victim row, a 21st hammer refresh address HREF_ADDR21 of a 21st victim row, and a 22nd hammer refresh address HREF_ADDR22 of a 22nd victim row in sequence based on the hammer address HADDR of the aggressor row.

FIG. 15B illustrates a first series operation Series1. Referring to FIG. 15B, a refresh operation may be performed on an eleventh victim row received from the refresh controller (S2420). Thereafter, the row active operation described with reference to FIG. 13 may be performed on the eleventh victim row (S2421). However, in example embodiments, the row activation operation (S2421) for the eleventh victim row may not be provided.

FIG. 15C illustrates a second series operation Series2. Referring to FIG. 15C, a refresh operation may be performed on a twelfth victim row received from the refresh controller (S2430). Thereafter, the row active operation described with reference to FIG. 13 may be performed on the twelfth victim row (S2431). However, in example embodiments, the row activation operation (S2421) for the eleventh victim row may not be provided.

FIG. 15D illustrates a third series operation Series3. Referring to FIG. 15D, a refresh operation may be performed on a 21st victim row received from the refresh controller (S2440). Thereafter, the row active operation described with reference to FIG. 13 may be performed on the 21st victim row (S2441).

FIG. 15E illustrates a fourth series operation Series4. Referring to FIG. 15E, a refresh operation may be performed on a 22nd victim row received from the refresh controller (S2450). Thereafter, the row active operation described with reference to FIG. 13 may be performed on the 22nd victim row (S2451).

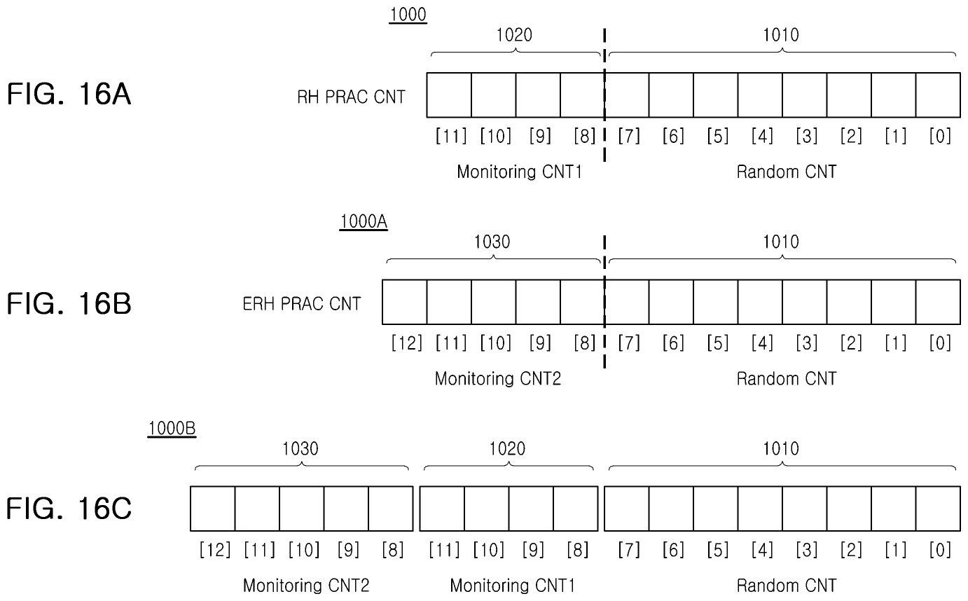

FIGS. 16A to 16C are diagrams illustrating count values according to an example embodiment.

Referring to FIG. 16A, row hammer count cells, which are a portion of memory cells included in a plurality of memory cell rows, may store row hammer PRAC count data 1000 obtained by binarizing a row hammer PRAC count value RH PRAC CNT. A portion of row hammer count cells may store N-bit lower data 1010, and the other portion of row hammer count cells may store M-bit first upper data 1020.

Referring to FIG. 16B, extended row hammer count cells, which are a portion of memory cells included in a plurality of memory cell rows, may store extended row hammer PRAC count data 1000A obtained by binarizing an extended row hammer PRAC count value ERH PRAC CNT. A portion of extended row hammer count cells may store N-bit lower data 1010, and the other portion of extended row hammer count cells may store L-bit second upper data 1030. Here, each of L, M, and N may be a natural number of being equal to or greater than 1.

Referring to FIG. 16C, count cells, which are a portion of memory cells included in a plurality of memory cell rows, may store count data 1000B representing a count value. The count data 1000B may include row hammer PRAC count data 1000 corresponding to the row hammer PRAC count value RH PRAC CNT and the extended row hammer PRAC count data 1000A corresponding to the extended row hammer PRAC count value ERH PRAC CNT representing the number of accesses of each of the plurality of memory cell rows. A portion of count cells may store N-bit lower data 1010, the other portion of count cells may store M-bit first upper data 1020, and the other portion of count cells may store L-bit second upper data 1030. That is, the row hammer PRAC count data 1000 and the extended row hammer PRAC count data 1000A may share the N-bit lower data 1010. The lower data 1010 may correspond to a random count value random CNT, the first upper data 1020 may correspond to a first monitoring count value monitoring CNT1, and the second upper data 1030 may correspond to a second monitoring count value monitoring CNT2.

According to an example embodiment, the ratio of the first upper data 1020, the second upper data 1030, and the lower data 1010 may be arbitrarily varied. For example, the size of the first upper data 1020 may be 4 bits, the size of the second upper data 1030 may be 5 bits, and the size of the lower data 1010 may be 8 bits. In another example embodiment, the ratio of the size of the first upper data 1020 and/or the second upper data 1030 to the size of the count data 1000B may be 30% or more, respectively. However, the ratio of the first upper data 1020 and the second upper data 1030 according to an example embodiment is not limited thereto.

In an example embodiment, when booting the memory device, an initial value of the lower data 1010 among the count data 1000B may be determined as a random value, and initial values of the first upper data 1020 and the second upper data 1030 of the count data 1000B may be determined as 0. That is, the initial value of the random count value random CNT may be determined as a random value, and the initial values of the first monitoring count value monitoring CNT1 and the second monitoring count value monitoring CNT2 may be determined as 0.

Whenever a memory cell row is accessed, the row hammer PRAC count value RH PRAC CNT and the extended row hammer PRAC count value ERH PRAC CNT of the memory cell row may be increased by 1. When the row hammer PRAC count value RH PRAC CNT and the extended row hammer PRAC count value ERH PRAC CNT increase and reach a predetermined reference value or more, the access row may become a target for management as a candidate aggressor row. For example, count cells 1000 may store count data 1000B including 4-bit first upper data 1020, 5-bit second upper data 1030, and 8-bit lower data 1010. In this case, when the row hammer PRAC count value RH PRAC CNT or the extended row hammer PRAC count value ERH PRAC CNT is 256 or more, that is, when the first monitoring count Monitoring CNT1 value or the second monitoring count value monitoring CNT2 is greater than 0, the access row may be a target of management as a candidate aggressor row.

When a row hammer refresh operation is performed on the aggressor row, the row hammer PRAC count value RH PRAC CNT of the aggressor row may be initialized, and the victim rows based on the aggressor row may perform a refresh operation. In an example embodiment, when the row hammer PRAC count value RH PRAC CNT of the aggressor row is initialized, the random count value random CNT may be maintained, and the first monitoring count value monitoring CNT1 may be initialized to 0. That is, the lower data 1010 of the aggressor row may be maintained, and the first upper data 1020 may be reset to 0.

When an extended row hammer refresh operation is performed on an aggressor row, the extended row hammer PRAC count value ERH PRAC CNT of the aggressor row may be initialized, and the victim rows based on the aggressor row may perform a refresh operation. In an example embodiment, when the extended row hammer PRAC count value ERH PRAC CNT of the aggressor row is initialized, the random count value random CNT may be maintained, and the second monitoring count value monitoring CNT2 may be initialized to 0. That is, the lower data 1010 of the aggressor row may be maintained, and the second upper data 1030 may be reset to 0.

When a specific memory cell row is intensively accessed, the degree of electromagnetic coupling between victim rows adjacent to the access row may be different. That is, strength for the row hammer may be different for each victim row depending on degree of proximity to the aggressor row. For example, referring to FIG. 10, when the aggressor row is accessed by N number of times in the eleventh victim row and the twelfth victim, stored data may be modified. When the aggressor row is accessed by 2N number of times in the 21st victim row and the 22nd victim row, stored data may be modified. In an example embodiment, by setting upper data separately depending on the degree of proximity to the candidate aggressor row, defend against row hammer may be performed. Accordingly, a refresh operation may be performed more efficiently, and a memory device maintaining high defense against row hammer attacks may be provided.

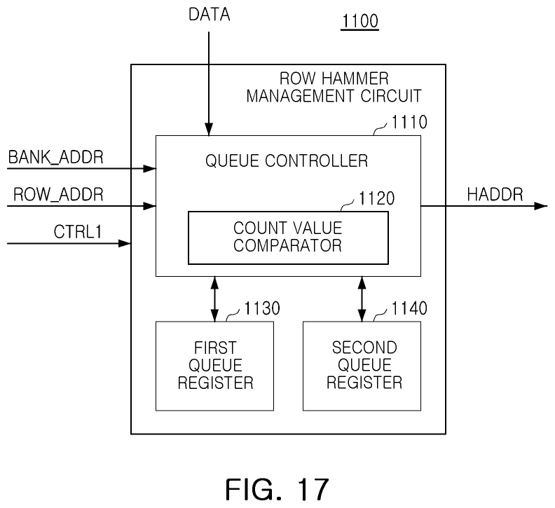

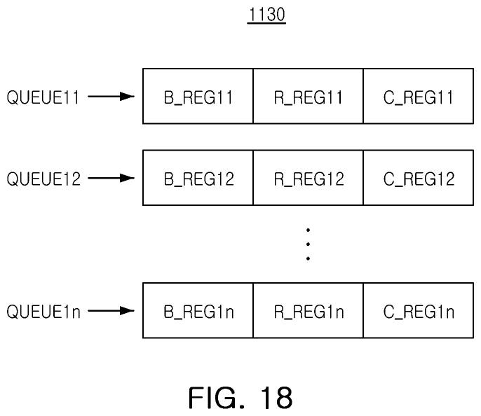

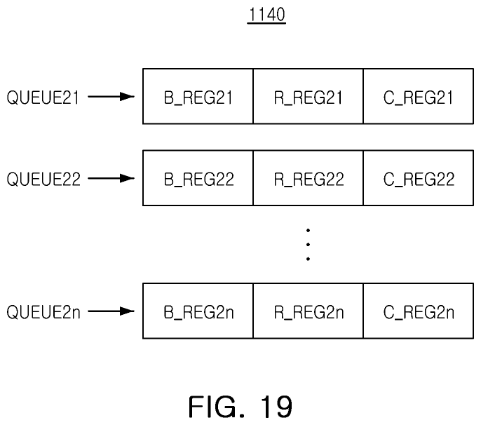

FIG. 17 is a block diagram illustrating a row hammer management circuit according to an example embodiment. FIGS. 18 and 19 are diagrams illustrating a queue register according to an example embodiment.

Referring to FIG. 17, a row hammer management circuit 1100 according to an example embodiment may include a queue controller 1110, a first queue register 1130, and a second queue register 1140. The queue controller 1110 according to FIG. 17 may be similar to the queue controller 610 described with reference to FIG. 7. Also, the first queue register 1130 and the second queue register 1140 according to FIG. 17 may be similar to the queue register 630 described with reference to FIG. 7.

Referring to FIG. 18, each of the first queues QUEUE11-QUEUE1n stored in the first queue register 1130 may include bank registers B_REG11-B_REG1n storing bank addresses, row registers R_REG11-R_REG1n storing row addresses, and count registers C_REG11-C_REG1n storing row hammer PRAC count data as count data. In an example embodiment, the count registers C_REG11-C_REG1n of the first queue may store first upper data among the row hammer PRAC count data as count data. However, the count data stored by the first queue according to an example embodiment is not limited thereto.

Referring to FIG. 19, each of the second queues QUEUE21-QUEUE2n stored in the second queue register 1140 may include bank registers B_REG21-B_REG2n storing bank addresses, row registers R_REG21-R_REG2n storing row addresses, and count registers C_REG21-C_REG2n storing extended row hammer PRAC count data as count data. In an example embodiment, the count registers C_REG21-C_REG2n of the second queue may store second upper data among the extended row hammer PRAC count data as count data. However, the count data stored by the second queue according to an example embodiment is not limited thereto. A queue may be a storage space implemented with a flip-flop, a latch, a buffer circuit, an SRAM, or the like, and may operate in a first-in-first-out manner.

In an example embodiment, a memory device maintaining high defense capability against a row hammer attack while performing a row hammer refresh operation with one first queue and one second queue may be provided. However, the number of the first queue and the second queue according to an example embodiment is not limited thereto.

Referring to FIGS. 17 to 19, a queue controller 1110 may include a count value comparator 1120, or the like. The count value comparator 1120 may compare count data stored in count registers C_REG11-C_REG1n of the first queue register 1130 with row hammer PRAC count data of an access row. Also, pieces of count data stored in count registers C_REG21-C_REG2n of the second queue register 1140 may be compared with count data of an access row.

The queue controller 1110 may control the queue registers 1130 and 1140 based on address signals BANK_ADDR and ROW_ADDR and a first control signal CTRL1 received from the memory controller. The address signals BANK_ADDR and ROW_ADDR may include the bank address BANK_ADDR and the row address ROW_ADDR. The queue controller 1110 may change the data stored in the queue based on the comparison result of the count value comparator 1120. The hammer address HADDR among the candidate aggressor rows may be determined and provided based on the count values of each of the candidate aggressor rows stored in the queue registers 1130 and 1140 according to the first control signal CTRL1. In an example embodiment, when data is stored in the queues of the queue registers 1130 and 1140, the memory controller may transmit the first control signal CTRL1 to output the row hammer address for the row hammer refresh operation.

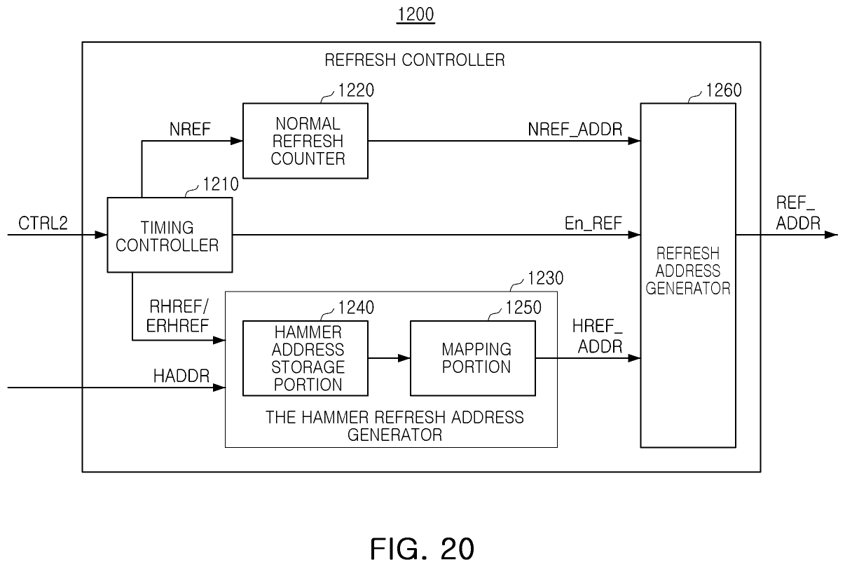

FIG. 20 is a block diagram illustrating a refresh controller according to an example embodiment.

Referring to FIG. 20, a refresh controller 1200 may include a timing controller 1210, a normal refresh counter 1220, a hammer refresh address generator 1230, and a refresh address generator 1260. The timing controller 1210, the normal refresh counter 1220, the hammer refresh address generator 1230, and the refresh address generator 1260 may be similar to the timing controller 610, the normal refresh counter 620, the hammer refresh address generator 630, and the refresh address generator 660 described above with reference to FIG. 8. However, the timing controller 1210 may receive a second control signal CTRL2 from the memory controller and may output a normal refresh signal NREF, a row hammer refresh signal RHREF, or an extended row hammer refresh signal ERHREF.

Referring to FIGS. 10 and 20, in an example embodiment, when the timing controller 1210 provides a row hammer refresh signal RHREF to the hammer refresh address generator 1230, the hammer refresh address generator 1230 may output an address HREF_ADDR11 of an eleventh victim row and an address HREF_ADDR12 of a twelfth victim row for the received row hammer address HADDR as the hammer refresh address HREF_ADDR in sequence. As another example embodiment, when the timing controller 1210 provides an extended row hammer refresh signal ERHREF to the hammer refresh address generator 1230, the hammer refresh address generator 1230 may output an address HREF_ADDR 21 of a 21st victim row and an address HREF_ADDR 22 of a 22nd victim row for the received row hammer address HADDR as the hammer refresh address HREF_ADDR in sequence.

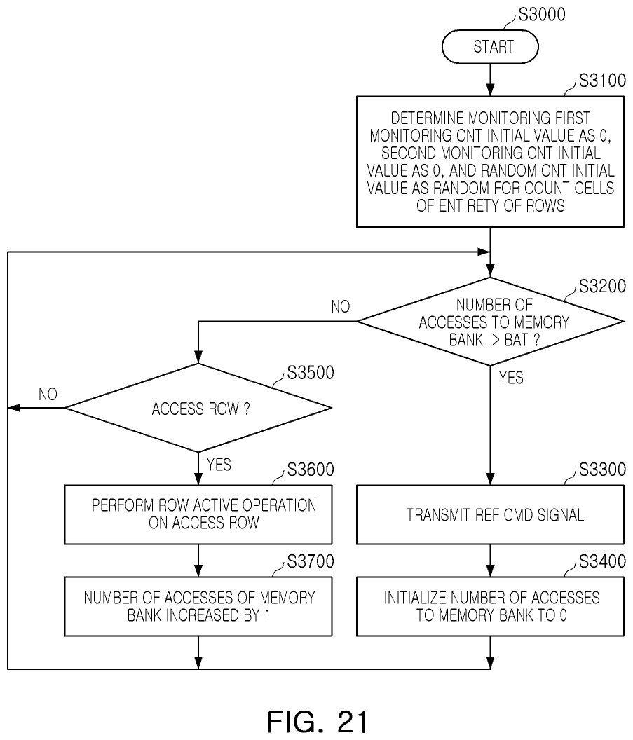

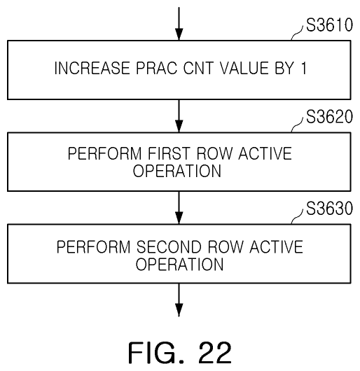

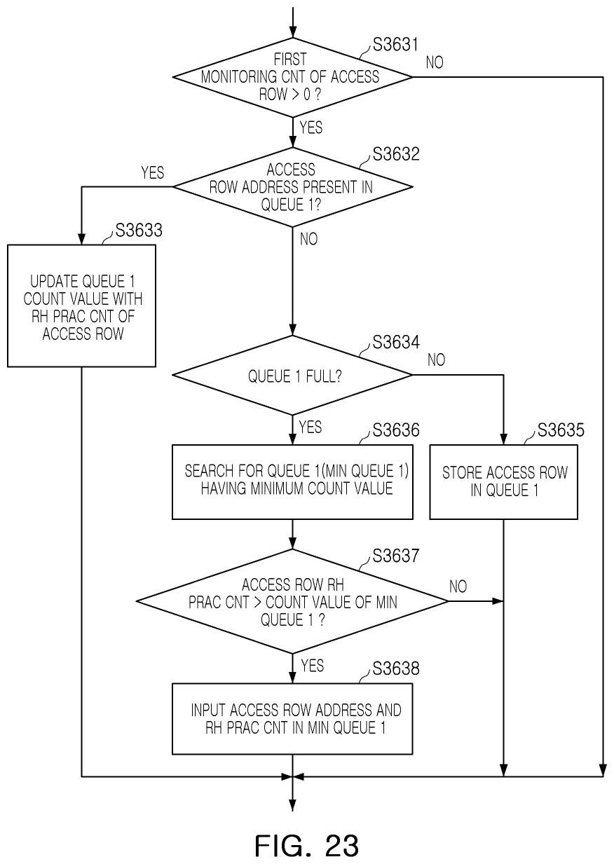

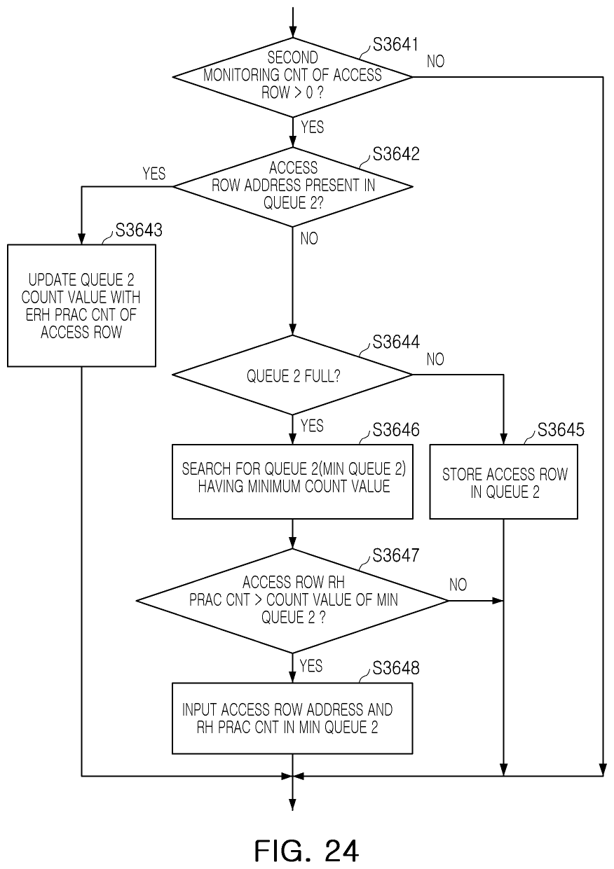

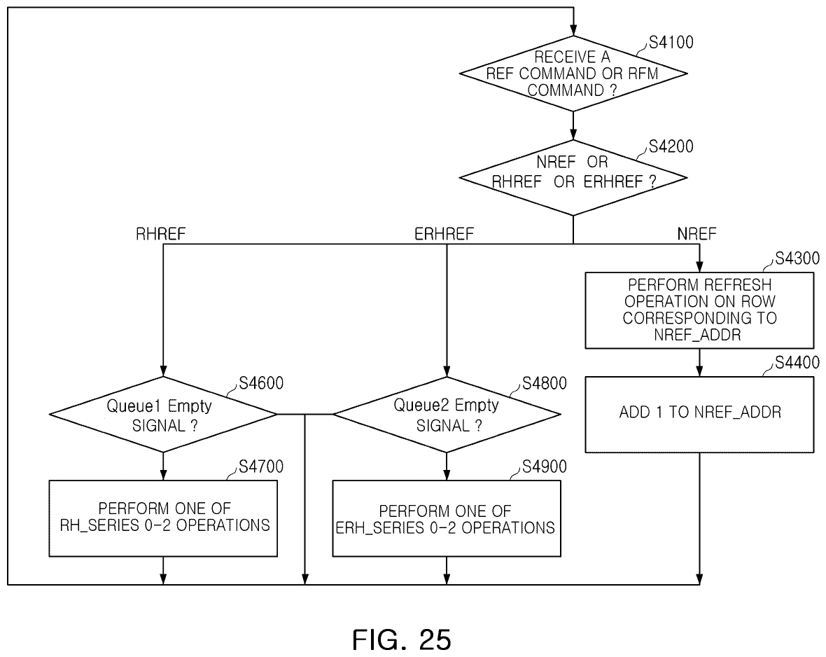

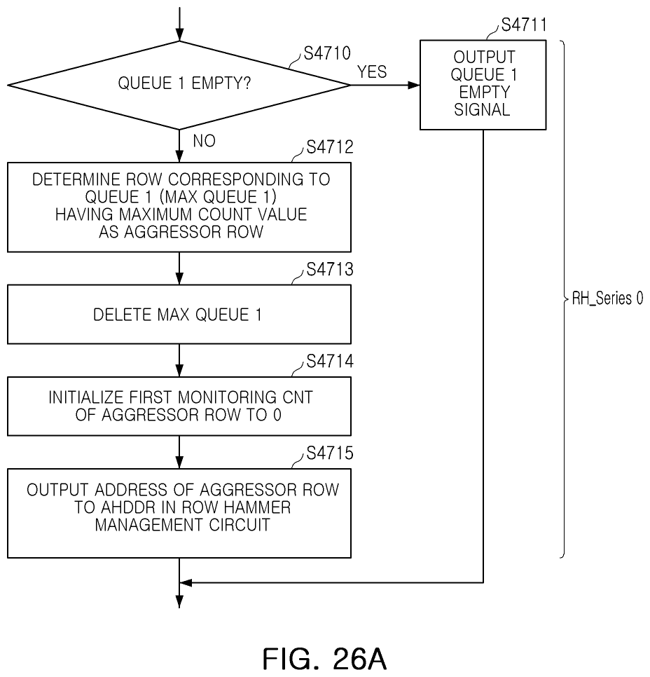

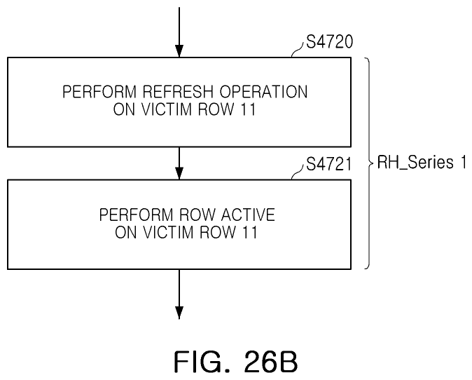

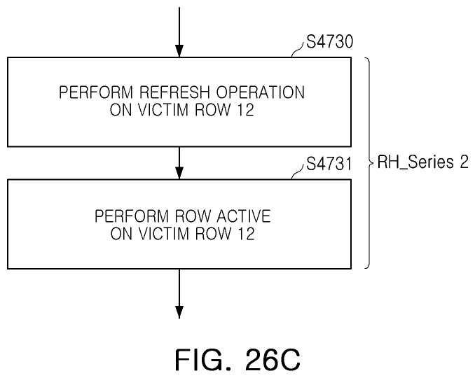

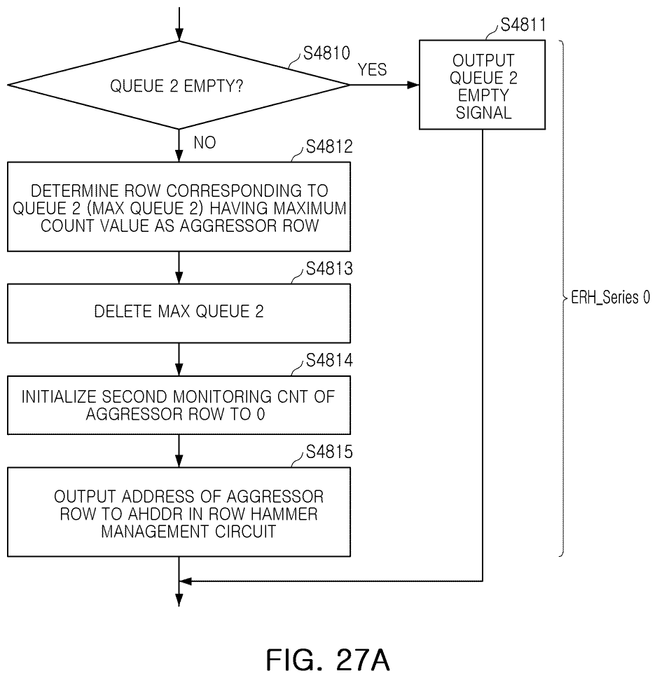

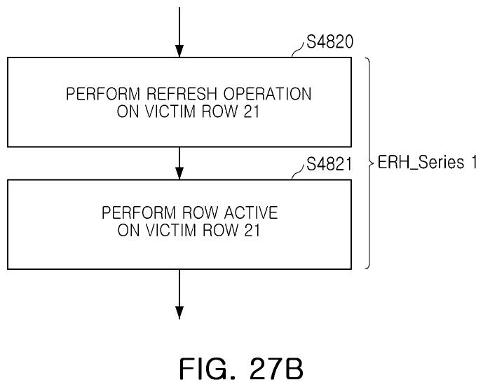

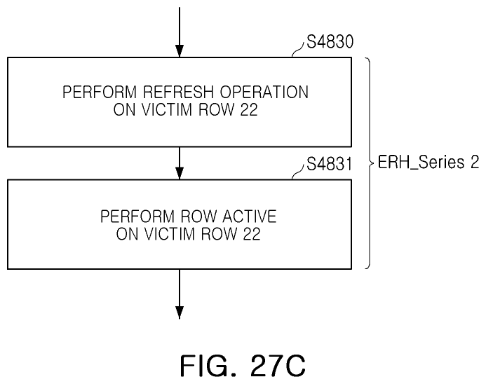

FIGS. 21 to 27C are flowcharts illustrating operations of a memory system according to an example embodiment.

FIG. 21 may be a flowchart illustrating operations of a refresh control logic among operations of the memory device according to an example embodiment. When the memory device starts booting (S3000), before exchanging data, for the count cells of the entirety of memory cell rows of the memory device, the initial value of the lower data may be arbitrarily determined for each memory cell row, and the initial values of the first upper data and the second upper data may be determined as 0 (S3100). In other words, for the count value of each memory cell row, the random count value may be determined as a random value, and the first monitoring count value and the second monitoring count value may be determined as 0. Thereafter, the number of accesses of each of the plurality of memory banks may be compared with the BAT value during the active timing (S3200).

When the number of accesses of at least one of the plurality of memory banks is the BAT value or more, the refresh control logic may include a refresh command in the command signal and may transmit the command to the memory device (S3300). Thereafter, the number of accesses for the corresponding memory bank may be initialized to 0 (S3400).

When the entirety of the plurality of memory banks have the number of accesses less than the BAT value, the memory controller may access the memory cell row, and the refresh control logic may sense this (S3500). When the access to the memory cell row is sensed, a row active operation may be performed for the access row (S3600). Thereafter, the number of accesses for the memory bank including the access row may be increased by 1 (S3700).

FIG. 22 may be a flowchart illustrating a row active operation described with reference to FIG. 21. As described above, when the access to the memory cell row is sensed, a row active operation may be performed for the access row. First, the PRAC count value RH PRAC CNT and ERH PRAC CNT stored in the count cell included in the access row may be increased by 1 (S3610). Thereafter, the first row active operation may be performed (S3620), and the second row active operation may be performed thereafter (S3630).

FIG. 23 may be a flowchart illustrating a first row active operation described with reference to FIG. 22. First, it may be determined whether the first monitoring count value of the access row is greater than 0, that is, whether data is input to the first upper data (S3631). When the first monitoring count value is 0, it may not be necessary to manage the access row. When the first monitoring count value is greater than 0, it may be determined that it may be necessary to manage the access row. In this case, it may be determined whether the address of the access row is present in the first queue included in the first queue register (S3632). Conversely, when there is the address of the access row in the first queue, the count data of the first queue storing the address of the access row may be updated with the row hammer PRAC count data corresponding to the row hammer PRAC count value of the access row (S3633). Conversely, when the address of the access row is not present in the first queue, it may be determined whether there is an empty space to store the address of the access row in the first queue, that is, whether the first queue is full (S3634).

When an empty space to store the address of the access row is present in the first queue, the address of the access row may be newly stored in the first queue (S3635). When the first queue is full, the pieces of count data stored in the first queue may be compared with each other and may search for a minimum queue having the smallest count value corresponding to the count data (S3636). Thereafter, the count value of the minimum queue may be compared with the row hammer PRAC count value of the access row (S3637). When the row hammer PRAC count value of the access row is greater than the count value of the minimum queue, the row address stored in the minimum queue may be changed to the access row address, and the count data stored in the minimum queue may be changed to the row hammer PRAC count data corresponding to the row hammer PRAC count value of the access row (S3638).

FIG. 24 may be a flowchart illustrating a second row active operation described with reference to FIG. 22. First, it may be determined whether the second monitoring count value of the access row is greater than 0, that is, whether data is input to the second upper data (S3641). When the second monitoring count value is 0, it may not be necessary to manage the access row. On the contrary, when the second monitoring count value is greater than 0, it may be determined that it may be necessary to manage the access row. In this case, it may be determined whether the address of the access row is present in the second queue included in the second queue register (S3642). When the address of the access row is present in the second queue, the count data of the second queue storing the address of the access row may be updated with the adjacent row hammer PRAC count data of the access row (S3643). On the contrary, when the address of the access row is not present in the second queue, it may be determined whether there is an empty space in the second queue to store the address of the access row, that is, whether the second queue is full (S3644).

When there is an empty space in the second queue to store the address of the access row, the address of the access row may be newly stored in the second queue (S3645). When the second queue is full, pieces of count data stored in the second queue may be compared with each other and may search for a minimum queue having a smallest count value corresponding to the count data (S3646). Thereafter, the count data of the minimum queue may be compared with the adjacent row hammer PRAC count value of the access row (S3647). When the adjacent row hammer PRAC count value of the access row is greater than the count value of the minimum queue, the row address stored in the minimum queue may be changed to the access row address, and the count data stored in the minimum queue may be changed to the adjacent row hammer PRAC count data corresponding to the extended row hammer PRAC count value of the access row (S3648).

FIG. 25 may be a flowchart illustrating a refresh operation. The control logic circuit may provide a second control signal to a refresh controller for a refresh operation when receiving a refresh command or RFM command from the memory controller (S4100). When the timing controller in the refresh controller receives the second control signal, a normal refresh signal NREF may be transmitted to a normal refresh counter, or a row hammer refresh signal RHREF or an extended row hammer refresh signal ERHREF may be transmitted to a hammer refresh address generator (S4200).

When the timing controller outputs the normal refresh signal NREF, the timing controller may perform a normal refresh operation (S4300). The normal refresh counter may provide a normal refresh address NREF_ADDR representing an address changing sequentially in synchronization with the normal refresh signal NREF. For example, the normal refresh counter may increase a value of the normal refresh address NREF_ADDR by 1 whenever the normal refresh signal NREF is activated (S4400). By increasing the value of the normal refresh address NREF_ADDR by 1 as above, wordlines for the normal refresh operation may be selected in sequence one by one. In an example embodiment, two normal refresh operations may be performed during one refresh timing. In another example embodiment, four normal refresh operations may be performed during one refresh timing. However, the number of operations which may be performed during one refresh timing is not limited thereto.

When the timing controller outputs the row hammer refresh signal RHREF to the hammer refresh address generator, the first row hammer refresh operation may be performed. Before performing the first row hammer refresh operation, it may be determined whether a signal indicating that the first queue is empty is provided (S4600). When the signal indicating that the first queue is empty is not provided, a plurality of row hammer series operations RH_Series0-RH_Series2 may be performed in sequence (S4700). In an example embodiment, two row hammer series operations may be performed during one refresh timing. In another example embodiment, four row hammer series operations may be performed during one refresh timing. However, the number of operations performed during one refresh timing is not limited thereto.

When the timing controller outputs the extended row hammer refresh signal ERHREF to the hammer refresh address generator, the second row hammer refresh operation may be performed. Before performing the second row hammer refresh operation, it may be determined whether a signal indicating that the second queue is empty is provided (S4800). When the signal indicating that the second queue is empty is not provided, a plurality of extended row hammer series operations ERH_Series0-ERH_Series2 may be performed in sequence (S4900). In an example embodiment, two extended row hammer series operations may be performed during one refresh timing. In another example embodiment, four extended row hammer series operations may be performed during one refresh timing. However, the number of operations performed during one refresh timing is not limited thereto.

FIG. 26A to FIG. 26C may be flowcharts illustrating a plurality of row hammer series operations RH_Series0-RH_Series2 described with reference to FIG. 25. A plurality of row hammer series operations RH_Series0-RH_Series2 may be performed in sequence and may be performed throughout a plurality of row hammer refresh timings.

FIG. 26A may illustrate the 0th row hammer series operation RH_Series0. Referring to FIG. 26A, first, the control logic circuit may determine whether the first queue is empty and may determine whether to perform the first row hammer refresh operation (S4710). When the first queue is empty, the control logic circuit may output a signal indicating that the first queue is empty (S4711), and thereafter, the row hammer refresh operation may not be performed during the row hammer refresh timing during which the corresponding row hammer series operation is performed.

When the first queue is not empty, a maximum queue having a largest value among count data stored in the first queue may be found, and a candidate aggressor row indicated by a row address stored in the maximum queue may be selected as an aggressor row (S4712). Thereafter, the maximum queue may be deleted (S4713), and the first monitoring count value of the aggressor row may be initialized to 0 (S4714). Thereafter, the row hammer management circuit may output an address of the aggressor row to the refresh controller as a hammer address HADDR (S4715). The refresh controller may generate a plurality of row hammer refresh addresses HREF_ADDR based on the hammer address HADDR in sequence. The row hammer refresh address HREF_ADDR may be an address of a row physically adjacent to the row corresponding to the row hammer address HADDR. Referring to FIG. 10, the refresh controller may output the eleventh hammer refresh address HREF_ADDR11 of the eleventh victim row and the twelfth hammer refresh address HREF_ADDR12 of the twelfth victim row as the hammer refresh address HREF_ADDR based on the hammer address HADDR of the aggressor row.

FIG. 26B may illustrate a first row hammer series operation RH_Series1. Referring to FIG. 26B, a refresh operation may be performed on the eleventh victim row received from the refresh controller (S4720). Thereafter, the row active operation described with reference to FIG. 22 may be performed on the eleventh victim row (S4721).

FIG. 26C may illustrate the second row hammer series operation RH_Series2. Referring to FIG. 26C, a refresh operation may be performed on the twelfth victim row received from the refresh controller (S4730). Thereafter, a row active operation described with reference to FIG. 22 may be performed on the twelfth victim row (S4731).

FIG. 27A to FIG. 27C may be a flowchart illustrating a plurality of extended row hammer series operations ERH_Series0-ERH_Series2 described with reference to FIG. 25. A plurality of extended row hammer series operations ERH_Series0-ERH_Series2 may be performed in order and may be performed throughout a plurality of row hammer refresh timings.

FIG. 27A may illustrate a 0th extended row hammer series operation ERH_Series0. Referring to FIG. 27A, first, the control logic circuit may determine whether to perform the second row hammer refresh operation by determining whether the second queue is empty (S4810). When the second queue is empty, the control logic circuit may output a signal indicating that the second queue is empty (S4811), and thereafter, the row hammer refresh operation may not be performed during the row hammer refresh timing during which the corresponding row hammer series operation is performed.

When the second queue is not empty, a maximum queue having a largest value among count data stored in the second queue may be found, and a candidate aggressor row indicated by a row address stored in the maximum queue may be selected as an aggressor row (S4812). Thereafter, the maximum queue may be deleted (S4813), and the second monitoring count value of the aggressor row may be initialized to 0 (S4814). Thereafter, the row hammer management circuit may output an address of the aggressor row to the refresh controller as a hammer address HADDR (S4815). The refresh controller may generate a plurality of row hammer refresh addresses HREF_ADDR in sequence based on the hammer address HADDR. The row hammer refresh address HREF_ADDR may be an address of a row adjacent to a row physically adjacent to the row corresponding to the row hammer address HADDR. Referring to FIG. 10, the refresh controller may output the 21st hammer refresh address HREF_ADDR21 of the 21st victim row and the 22nd hammer refresh address HREF_ADDR22 of the 22nd victim row as the hammer refresh address HREF_ADDR based on the hammer address HADDR of the aggressor row.

FIG. 27B may illustrate a second row hammer series operation ERH_Series1. Referring to FIG. 27B, a refresh operation may be performed on the 21st victim row received from the refresh controller (S4820). Thereafter, the row active operation described with reference to FIG. 22 may be performed on the 21st victim row (S4821).

FIG. 27C may illustrate a second row hammer series operation ERH_Series2. Referring to FIG. 27C, a refresh operation may be performed on the 22nd victim row received from the refresh controller (S4830). Thereafter, the row active operation described with reference to FIG. 22 may be performed on the 22nd victim row (S4831).

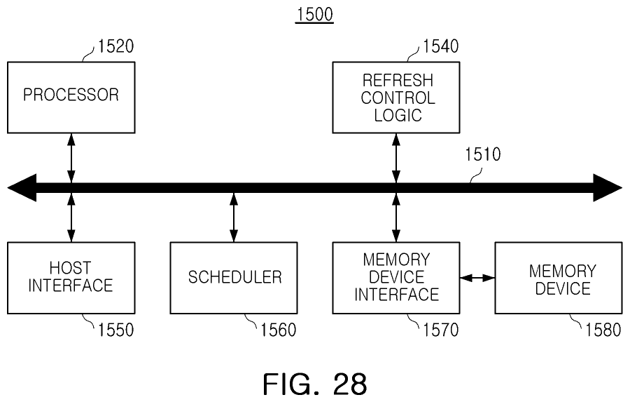

FIG. 28 is a block diagram illustrating components of a memory controller according to an example embodiment.

Referring to FIG. 28, a memory controller 1500 may include a processor 1520, a refresh control logic 1540, a host interface 1550, a scheduler 1560, and a memory device interface 1570, connected to each other through a bus 1510. The processor 1520 may control overall operations of each component of the memory system. The processor 1520 may be implemented as at least one of various processing units, such as a central processing unit (CPU), an application processor (AP), and a graphic processing unit (GPU).

The refresh control logic 1540 may generate a refresh signal refreshing a plurality of memory cell rows. The host interface 1550 may perform interfacing with a host. The memory device interface 1570 may perform interfacing with a semiconductor memory device 1580. A scheduler 1560 may manage scheduling and transmission of sequences of commands generated in the memory controller 1500.

According to the aforementioned example embodiments, when a system including a memory device is booted, upper data of the count data representing the number of accesses to each of a plurality of memory cell rows may be initialized to 0, and the lower data may be initialized to a random value. Also, in operation of initializing the count data of the aggressor row, by maintaining the lower data and resetting the upper data to 0, the number of accesses may not be estimated externally, and row hammer may be swiftly detected even with a small number of queues. Accordingly, a memory device having high defense against row hammer, a memory system, and an operation method thereof may be provided.

While the example embodiments have been illustrated and described above, it will be configured as apparent to those skilled in the art that modifications and variations could be made without departing from the scope of the present disclosure as defined by the appended claims.

What is claimed is:

1. A memory device, comprising:
a plurality of memory banks including a memory cell array including a plurality of memory cell rows disposed in the memory cell array, wherein each of the memory cell array includes a row decoder connected to the plurality of memory cell rows;
a row hammer management circuit configured to generate a row hammer address;
a refresh controller configured to provide one of a normal refresh address for a normal refresh operation, and a row hammer refresh address for a row hammer refresh operation based on the row hammer address to the row decoder as a refresh address;
a control logic circuit configured to control the row decoder, the row hammer management circuit, and the refresh controller,
wherein each of the plurality of memory cell rows includes count cells configured to store count data corresponding to a number of accesses,
wherein the count data includes N bits of lower data and M bits of first upper data, where each of M and N is a natural number of being equal to or greater than 1, and
wherein an initial value of the lower data is determined arbitrarily, and an initial value of the first upper data is determined as 0.

2. The memory device of claim 1,
wherein the row hammer management circuit includes a queue register configured to store at least one queue and a queue controller configured to control the at least one queue,
wherein the at least one queue stores an address of a candidate aggressor row intensively accessed among the plurality of memory cell rows and count data of the candidate aggressor row,
wherein the queue controller is configured to provide an address of the candidate aggressor row to the refresh controller as the row hammer address, and
wherein the control logic circuit is configured to initialize the first upper data of the count data of the candidate aggressor row to 0.

3. The memory device of claim 2, wherein the at least one queue includes a bank address register configured to store an address of a candidate memory bank including a candidate aggressor row, a row address register configured to store the address of the candidate aggressor row, and a count register configured to store the count data of the candidate aggressor row as queue count data.

4. The memory device of claim 3,
wherein the queue controller includes a count value comparator, and
wherein, when a first memory cell row among the plurality of memory cell rows is accessed, the count value comparator is configured to compare upper data of the first memory cell row with count data of a first queue among the at least one queue stored in the queue register and to change data stored in the first queue based on a result of the comparing.

5. The memory device of claim 1, wherein a ratio of a size of the first upper data to a size of the count data is equal to or greater than 30%.

6. The memory device of claim 1,
wherein the refresh controller includes a refresh address generator and a hammer refresh address generator configured to provide a row hammer refresh address to the refresh address generator for the row hammer refresh operation, and
wherein the hammer refresh address generator is configured to provide an address of a plurality of victim rows physically adjacent to a memory cell row corresponding to the row hammer address to the refresh address generator as the row hammer refresh address.

7. The memory device of claim 6,
wherein the refresh controller further includes a normal refresh counter and a timing controller,
wherein the normal refresh counter is configured to provide a normal refresh address for the normal refresh operation during the refresh operation, and
wherein the timing controller is configured to generate a normal refresh signal, a row hammer refresh signal, and a refresh operation signal based on a control signal provided from the memory controller.

8. The memory device of claim 7,
wherein the refresh controller further includes a refresh address generator, and
wherein the refresh address generator is configured to provide one of the normal refresh addresses and the row hammer refresh address to the row decoder as the refresh address based on the refresh operation signal.

9. The memory device of claim 1,
wherein the count data further includes second upper data of L bit size, where L is a natural number of being equal to or greater than 1, and
wherein an initial value of the second upper data is determined as 0.

10. The memory device of claim 9,
wherein the row hammer management circuit includes a first queue register and a second queue register configured to store at least one queue, and a queue controller configured to control the at least one queue,
wherein a first queue among the at least one queue stored in the first queue register stores an address of a candidate aggressor row intensively accessed among the plurality of memory cell rows and a row hammer PRAC count data among count data of the candidate aggressor row,
wherein a second queue among the at least one queue stored in the second queue register stores an address of the candidate aggressor row and extended row hammer PRAC count data among the count data of the candidate aggressor row,
wherein, when the first control signal is input from the memory controller, the queue controller is further configured to determine an attack row based on at least one first queue, to provide an address of the attack row as the row hammer address, and to initialize first upper data of the attack row to 0, and
wherein, based on that a second control signal is input from the memory controller, the queue controller is further configured to determine the attack row based on at least one second queue, to provide an address of the attack row as the row hammer address, and to initialize second upper data of the attack row to 0.

11. The memory device of claim 10,
wherein the first queue includes a bank address register configured to store an address of a candidate memory bank including the candidate aggressor row, a row address register configured to store the address of the candidate aggressor row, and a first count register configured to store row hammer PRAC count data of the candidate aggressor row as queue count data, and
wherein the second queue includes the bank address register, the row address register, and a second count register configured to store extended row hammer PRAC count data of the candidate aggressor row as queue count data.

12. The memory device of claim 10,
wherein the queue controller includes at least one count value comparator,
wherein, based on that the first memory cell row among the plurality of memory cell rows is accessed, the at least one count value comparator is configured to change data stored in the first queue based on a result of comparing the row hammer PRAC count data of the first memory cell row with queue count data of the at least one first queue, and to change data stored in the second queue based on a result of comparing the extended row hammer PRAC count data of the first memory cell row with queue count data of the at least one second queue.

13. The memory device of claim 9,
wherein the refresh controller includes a refresh address generator and a hammer refresh address generator configured to provide a row hammer refresh address for the row hammer refresh operation to the refresh address generator, and
wherein the hammer refresh address generator is further configured to provide an address of a plurality of victim rows physically adjacent to a row corresponding to the hammer address to a hammer refresh address.

14. The memory device of claim 13,
wherein the refresh controller further includes a normal refresh counter and a timing controller,
wherein the normal refresh counter is configured to provide a normal refresh address for the normal refresh operation during the refresh operation, and
wherein the timing controller is configured to generate a normal refresh signal, a row hammer refresh signal, and a refresh operation signal based on a control signal provided from the memory controller.

15. The memory device of claim 14,
wherein the refresh controller further includes a refresh address generator, and
wherein the refresh address generator is configured to provide one of the normal refresh address and the row hammer refresh address to the row decoder as the refresh address based on the refresh operation signal.

16. A method of operating a memory device, the method comprising:
determining an initial value of upper data among count data representing a number of accesses to each of a plurality of memory cell rows as 0, and determining an initial value of lower data among the count data as a random value;
searching a maximum queue having a highest count value corresponding to queue count data among at least one queue stored in a queue register among a plurality of queue registers;
determining a memory cell row corresponding to an address stored in the maximum queue among the plurality of memory cell rows as an attack row;
deleting data stored in the maximum queue;
resetting upper data of the attack row to 0; and
outputting an address of the attack row as a hammer address in a row hammer management circuit.

17. The method of claim 16, further comprising:
transferring a hammer refresh address representing addresses of a plurality of victim rows adjacent to the attack row to a refresh address generator by a hammer refresh address generator.

18. The method of claim 16,
wherein a first queue stored by a first queue register among the queue registers stores an address of a candidate aggressor row intensively accessed among the plurality of memory cell rows and first count data among count data of the candidate aggressor row, and
wherein the resetting of the upper data of the attack row to 0 includes resetting first upper data included in the first count data among the upper data of the attack row to 0.

19. A memory system, comprising:
a memory device configured to store data; and
a memory controller configured to transmit a command signal, an address signal, a clock signal, and a data signal to the memory device,
wherein the memory controller includes a row hammer management circuit configured to generate a row hammer address,
wherein the memory device further includes:
a plurality of memory banks each including a memory cell array in which the plurality of memory cell rows are disposed, and a row decoder connected to the plurality of memory cell rows;
a refresh controller configured to provide one of a normal refresh address for a normal refresh operation and a row hammer refresh address for a row hammer refresh operation based on the row hammer address to the row decoder as a refresh address;
a control logic circuit configured to control the row decoder, the row hammer management circuit, and the refresh controller,
wherein each of the plurality of memory cell rows includes count cells configured to store count data corresponding to a number of accesses,
wherein the count data includes N bits of lower data and M bits of upper data, where each of M and N is a natural number of being equal to or greater than 1, and
wherein an initial value of the lower data is arbitrarily determined, and an initial value of the upper data is determined as 0.

20. The memory device of claim 19,
wherein the row hammer management circuit includes a queue register configured to store at least one queue and a queue controller configured to control the at least one queue,
wherein the at least one queue stores an address of a candidate aggressor row intensively accessed among the plurality of memory cell rows and upper data of count data of the candidate aggressor row, and
wherein the queue controller is configured to provide the address of the candidate aggressor row to the refresh controller as the row hammer address, and
wherein the control logic circuit is configured to initialize the upper data of count data of the candidate aggressor row to 0.
